(19) United States
(12) Patent Application Publication
(10) Pub. No.: US 2026/0136782 A1
(43) Pub. Date: May 14, 2026

(54) DISPLAY SUBSTRATE AND DISPLAY APPARATUS

(71) Applicant: BOE TECHNOLOGY GROUP CO., LTD., Beijing (CN)

(72) Inventors: Hao ZHANG, Beijing (CN); Jia ZHAO, Beijing (CN)

(21) Appl. No.: 18/704,117

(22) PCT Filed: Oct. 25, 2021
(86) PCT No.: PCT/CN2021/125990

§ 371 Date: Apr. 24, 2024

(51) Int. Cl. H10K 59/131; H10K 59/121

(52) U.S. Cl. CPC H10K 59/131; H10K 59/1213

(57) ABSTRACT

A display substrate and a display apparatus are provided. A display substrate is provided and includes a plurality of hollow apertures, a plurality of island regions separated by the plurality of hollow apertures and bridge regions connected between the island regions, where the display substrate further includes: a plurality of pixel units, provided in the island regions and the bridge regions.

### TECHNICAL FIELD

The present disclosure relates to a field of display technology, and more particularly a display substrate, a display apparatus.

### BACKGROUND

In the related art, a stretchable display substrate is usually implemented by defining a hollow aperture thereon, and the hollow aperture may separate the display substrate into a plurality of island regions, and pixel units may be provided in the island regions. However, the position where the hollow aperture is disposed cannot be provided with the pixel unit, which results in a low resolution of the stretchable display substrate.

It should be noted that the information disclosed in the Background section above is only for enhancing the understanding of the background of the present disclosure, and thus may include information that does not constitute prior art known to those of ordinary skill in the art.

### SUMMARY

According to an aspect of the present disclosure, a display substrate is provided and includes a plurality of hollow apertures, a plurality of island regions separated by the plurality of hollow apertures and bridge regions connected between the island regions, where the display substrate further includes: a plurality of pixel units, provided in the island regions and the bridge regions.

In an exemplary embodiment of the present disclosure, the plurality of island regions are distributed in rows and columns, each island region is connected to four bridge regions, and each island region is connected to four island regions adjacent to the island region in a row direction and a column direction, respectively, through the four bridge regions.

In an exemplary embodiment of the present disclosure, the hollow aperture is in I-shape and the I-shaped hollow aperture includes: two first strip-shaped apertures opposite to each other, and a second strip-shaped aperture connected between the two first strip-shaped apertures; the plurality of hollow apertures includes a plurality of first hollow apertures distributed in rows and columns and a plurality of second hollow apertures distributed in rows and columns, the second strip-shaped aperture of the first hollow aperture extends along the column direction and the second strip-shaped aperture of the second hollow aperture extends along the row direction; where the second hollow aperture is disposed between two adjacent first hollow apertures in the row direction, and the first hollow aperture is disposed between two adjacent second hollow apertures in the column direction; the first hollow apertures in adjacent columns and in adjacent rows are staggered in the column direction, the second hollow apertures in adjacent rows and in adjacent columns are staggered in the row direction, and the first strip-shaped apertures of two first hollow apertures arranged in a staggered manner and the first strip-shaped apertures of two second hollow apertures arranged in a staggered manner form the island region; the four bridge regions connected to the same island region include a first bridge region, a second bridge region, a third bridge region, and a fourth bridge region, at least a partial region of the first bridge region and the third bridge region is disposed between the second strip-shaped aperture of the first hollow aperture and the first strip-shaped aperture of the second hollow aperture, and at least a partial region of the second bridge region and the fourth bridge region is disposed between the first strip-shaped aperture of the first hollow aperture and the second strip-shaped aperture of the second hollow aperture.

In an exemplary embodiment of the present disclosure, each island region is provided with four pixel units distributed in a two-by-two array, and each bridge region is provided with six pixel units distributed in the same direction, and the six pixel units are spaced apart along an extension direction of the bridge region where the six pixel units are disposed.

In an exemplary embodiment of the present disclosure, the pixel unit includes a plurality of pixel driving circuits and a plurality of light emitting units in one-to-one correspondence with the pixel driving circuits.

In an exemplary embodiment of the present disclosure, the display substrate further includes: a base substrate; a first gate layer, disposed on a side of the base substrate, where the first gate layer includes: a first gate line, where the first gate line is disposed on the first bridge region and is connected to the pixel driving circuit disposed on the first bridge region of the same driving row; a second gate line, where the second gate line is disposed on the second bridge region and is connected to the pixel driving circuit disposed on the second bridge region in the same driving row, the first bridge region where the first gate line is disposed and the second bridge region where the second gate line is disposed are connected to the same island region, and the pixel driving circuit connected to the first gate line and the pixel driving circuit connected to the second gate line are disposed on the same driving row; a first source-drain layer, disposed on a side of the first gate layer facing away from the base substrate, where the first source-drain layer includes: a first connection line, where at least a partial structure of the first connection line is disposed on the first bridge region where the first gate line is disposed, and the first connection line is connected to the first gate line and the second gate line, respectively, through a via hole.

In an exemplary embodiment of the present disclosure, the first gate layer further includes: a third gate line, where at least a partial structure of the third gate line is disposed on the fourth bridge region, the fourth bridge region where the third gate line is disposed and the second bridge region where the second gate line is disposed are connected to the same island region; the plurality of island regions include a first island region and a second island region adjacent to each other in the row direction, the first island region and the second island region are connected through the fourth bridge region, and the third gate line disposed in the fourth bridge region is connected to the second gate line corresponding to the first island region and the second gate line corresponding to the second island region; where the second bridge region where the second gate line corresponding to the first island region is disposed is connected to the first island region, and the second bridge region where the second gate line corresponding to the second island region is disposed is connected to the second island region.

In an exemplary embodiment of the present disclosure, the display substrate further includes: a base substrate; a first gate layer, disposed on a side of the base substrate, where the first gate layer includes: a fourth gate line, where the fourth gate line is disposed on the fourth bridge region and is connected to the pixel driving circuit disposed in the fourth bridge region of the same driving row; a fifth gate line, where the fifth gate line is disposed on the third bridge region and is connected to the pixel driving circuit disposed in the third bridge region of the same driving row, and the pixel driving circuit connected to the fourth gate line and the pixel driving circuit connected to the fifth gate line are disposed on the same driving row; a first source-drain layer, disposed on a side of the first gate layer facing away from the base substrate, where the first source-drain layer includes: a second connection line, where at least a partial structure of the second connection line is disposed on the third bridge region where the fifth gate line is disposed, and the second connection line is connected to the fourth gate line and the fifth gate line, respectively, through a via hole.

In an exemplary embodiment of the present disclosure, the first gate layer further includes: a sixth gate line, where at least a partial structure of the sixth gate line is disposed on the second bridge region, the second bridge region where the sixth gate line is disposed and the fourth bridge region where the fourth gate line is disposed are connected to the same island region; the plurality of island regions further includes a first island region, a third island region disposed on the same row, the first island region and the third island region are connected through the second bridge region; the sixth gate line disposed on the second bridge region is connected to the fourth gate line corresponding to the first island region and the fourth gate line corresponding to the third island region; the fourth bridge region where the fourth gate line corresponding to the first island region is disposed is connected to the first island region, and the fourth bridge region where the fourth gate line corresponding to the third island region is disposed is connected to the third island region.

In an exemplary embodiment of the present disclosure, the display substrate further includes: a base substrate; a first gate layer, disposed on a side of the base substrate, where the first gate layer includes: a seventh gate line, where the seventh gate line is disposed on the first bridge region and is connected to the pixel driving circuit disposed in the first bridge region of the same driving row; an eighth gate line, where the eighth gate line is disposed on the island region and is connected to the pixel driving circuit disposed in the island region of the same driving row, the island region where the eighth gate line is disposed is connected to the first bridge region where the seventh gate line is disposed, and the pixel driving circuit connected to the seventh gate line and the pixel driving circuit connected to the eighth gate line are disposed on the same driving row; a first source-drain layer, disposed on a side of the first gate layer facing away from the base substrate, where the first source-drain layer includes: a third connection line, where at least a partial structure of the third connection line is disposed on the first bridge region where the seventh gate line is disposed, and the third connection line is connected to the seventh gate line and the eighth gate line, respectively, through a via hole.

In an exemplary embodiment of the present disclosure, the first gate layer further includes: a ninth gate line, where the ninth gate line is disposed on the third bridge region and is connected to the pixel driving circuit disposed in the third bridge region of the same driving row, the island region where the eighth gate line is disposed is connected to the third bridge region where the ninth gate line is disposed, and the pixel driving circuit connected to the ninth gate line and the pixel driving circuit connected to the eighth gate line are disposed on the same driving row; the first source-drain layer includes: a fourth connection line, where at least a partial structure of the fourth connection line is disposed on the third bridge region where the ninth gate line is disposed, and the fourth connection line is connected to the ninth gate line and the eighth gate line, respectively, through a via hole.

In an exemplary embodiment of the present disclosure, the first gate layer further includes: a tenth gate line, where at least a partial structure of the tenth gate line is disposed on the second bridge region, the second bridge region where the tenth gate line is disposed is connected to the island region where the eighth gate line is disposed; an eleventh gate line, where at least a partial structure of the eleventh gate line is disposed on the fourth bridge region, the fourth bridge region where the eleventh gate line is disposed is connected to the island region where the eighth gate line is disposed; the plurality of island regions include a first island region, a second island region, and a third island region disposed on the same row, the first island region is disposed between the second island region and the third island region, the first island region and the third island region are connected through the second bridge region, and the first island region and the second island region are connected through the fourth bridge region; the tenth gate line disposed in the second bridge region is connected to the fourth connection line corresponding to the first island region and the fourth connection line corresponding to the third island region through a via hole; the eleventh gate line disposed in the fourth bridge region is connected to the fourth connection line corresponding to the first island region and the fourth connection line corresponding to the second island region through a via hole; where the third bridge region where the fourth connection line corresponding to the first island region is disposed is connected to the first island region, the third bridge region where the fourth connection line corresponding to the third island region is disposed is connected to the third island region, and the third bridge region where the fourth connection line corresponding to the second island region is disposed is connected to the second island region.

In an exemplary embodiment of the present disclosure, the display substrate further includes: a base substrate; a first source-drain layer, disposed on a side of the base substrate, where the first source-drain layer includes: a first data line, disposed on the island region, as well as the first bridge region and the fourth bridge region that are connected to the island region, where the first data line is connected to the plurality of pixel driving circuits disposed in the first bridge region and the fourth bridge region of the same driving column; the plurality of island regions include a first island region and a fourth island region adjacent to each other in the column direction, the first island region and the fourth island region are connected through the third bridge region; a second source-drain layer, disposed on a side of the first source-drain layer facing away from the base substrate, where the second source-drain layer includes: a fifth connection line, where at least a partial structure of the fifth connection line is disposed on the third bridge region between the first island region and the fourth island region, and the fifth connection line is connected to the first data line corresponding to the first island region and the first data line corresponding to the fourth island region, respectively, through a via hole; the first data line corresponding to the first island region is disposed on the first island region as well as the first bridge region and the fourth bridge region that are connected to the first island region, and the first data line corresponding to the fourth island region is disposed on the fourth island region as well as the first bridge region and the fourth bridge region that are connected to the fourth island region.

In an exemplary embodiment of the present disclosure, the display substrate further includes: a base substrate; a first source-drain layer, disposed on a side of the base substrate, where the first source-drain layer includes: a second data line, disposed on the island region as well as the second bridge region and the fourth bridge region that are connected to the island region, where the second data line is connected to the plurality of pixel driving circuits disposed in the island region, the second bridge region and the fourth bridge region of the same driving column; the plurality of island regions include a first island region, a fourth island region, and a fifth island region disposed on the same column, where the first island region is disposed between the fourth island region and the fifth island region, the first island region and the fourth island region are connected through the third bridge region, and the first island region and the fifth island region are connected through the first bridge region; a second source-drain layer, disposed on a side of the first source-drain layer facing away from the base substrate, where the second source-drain layer includes: a sixth connection line, where at least a partial structure of the sixth connection line is disposed on the third bridge region between the first island region and the fourth island region, and the first bridge region between the first island region and the fifth island region, and the sixth connection line is connected to the second data line corresponding to the first island region, the second data line corresponding to the fourth island region, and the second data line corresponding to the fifth island region, respectively, through a via hole; the second data line corresponding to the first island region is disposed on the first island region, as well as the second bridge region and the fourth bridge region that are connected to the first island region, the second data line corresponding to the fourth island region is disposed on the fourth island region, as well as the second bridge region and the fourth bridge region that are connected to the fourth island region, and the second data line corresponding to the fifth island region is disposed on the fifth island region, as well as the second bridge region and the fourth bridge region that are connected to the fifth island region.

In an exemplary embodiment of the present disclosure, the display substrate further includes: a base substrate; a first source-drain layer, disposed on a side of the base substrate, where the first source-drain layer includes: a third data line, where the third data line is disposed on the island region, as well as the second bridge region and the third bridge region that are connected to the island region, the third data line is connected to the plurality of pixel driving circuits disposed in the second bridge region of the same driving column and third bridge region; the plurality of island regions include a first island region and a fifth island region adjacent to each other in the column direction, where the first island region and the fifth island region are connected through the first bridge region; a second source-drain layer, disposed on a side of the first source-drain layer facing away from the base substrate, where the second source-drain layer includes: a seventh connection line, where at least a partial structure of the seventh connection line is disposed on the first bridge region between the first island region and the fifth island region, and the seventh connection line is connected to the third data line corresponding to the first island region and the third data line corresponding to the fifth island region, respectively, through a via hole; the third data line corresponding to the first island region is disposed on the first island region, as well as the second bridge region and the third bridge region that are connected to the first island region, and the third data line corresponding to the fifth island region is disposed on the fifth island region, as well as the second bridge region and the third bridge region that are connected to the fifth island region.

In an exemplary embodiment of the present disclosure, the pixel driving circuits include capacitors, the capacitor includes first electrode, and the display substrate further includes: a base substrate; a first gate layer, disposed on a side of the base substrate; a second gate layer, disposed on a side of the first gate layer facing away from the base substrate, where the second gate layer includes: at least one first electrode line, where the first electrode line is disposed on the first bridge region, and in the first bridge region, the first electrodes of the capacitors disposed in the pixel driving circuit of the same driving row are connected to each other to form the first electrode line; at least one second electrode line, where the second electrode line is disposed on the island region; in the island region, the first electrodes of the capacitors disposed in the pixel driving circuit of the same driving row are connected to each other to form the second electrode line, and the first bridge region where the first electrode line is disposed is connected to the island region where the second electrode line is disposed; a first source-drain layer, disposed on a side of the second gate layer facing away from the base substrate, where the first source-drain layer includes: at least one first power line, where the first power line is disposed on the first bridge region, connected to the pixel driving circuit disposed in the first bridge region of the same driving column, and at least one first power line is connected to one second electrode line through a via hole; at least one second power line, where the second power line is disposed on the island region, the island region where the second power line is disposed is connected to the first bridge region where the first power line is disposed, and the second power line is connected to the pixel driving circuit disposed in the island region of the same driving column.

In an exemplary embodiment of the present disclosure, the second gate layer further includes: at least one third electrode line, where the third electrode line is disposed on the third bridge region; in the third bridge region, the first electrodes of the capacitors in the pixel driving circuit disposed on the same driving row are connected to each other to form the third electrode line, and the third bridge region where the third electrode line is disposed is connected to the island region where the second electrode line is disposed; the first source-drain layer further includes: at least one third power line, where the third power line is disposed on the third bridge region where the third electrode line is disposed, connected to the pixel driving circuit disposed in the third bridge region of the same driving column; an eighth connection line, where the eighth connection line is disposed on the third bridge region where the third power line is disposed, and connected to one second power line and one third electrode line.

In an exemplary embodiment of the present disclosure, the second gate layer further includes: a fourth electrode line, where the fourth electrode line is disposed on the fourth bridge region; in the fourth bridge region, the first electrodes of the capacitors in the pixel driving circuit disposed on the same driving row are connected to each other to form the fourth electrode line, and the fourth bridge region where the fourth electrode line is disposed is connected to the island region where the second electrode line is disposed; the first source-drain layer further includes: at least one fourth power line, where the fourth power line is disposed on the fourth bridge region where the fourth electrode line is disposed, connected to the pixel driving circuit disposed in the fourth bridge region of the same driving column; where at least one fourth power line includes a first power sub-line, and the first power sub-line is connected to one second power line.

In an exemplary embodiment of the present disclosure, the second gate layer further includes: a fifth electrode line, where the fifth electrode line is disposed on the second bridge region; in the second bridge region, the first electrodes of the capacitors in the pixel driving circuit disposed on the same driving row are connected to each other to form the fifth electrode line, and the second bridge region where the fifth electrode line is disposed is connected to the island region where the second electrode line is disposed; the first source-drain layer further includes: at least one fifth power line, where the fifth power line is disposed on the second bridge region where the fifth electrode line is disposed, and connected to the pixel driving circuit disposed in the second bridge region of the same driving column; at least one fifth power line includes a second power sub-line, and the second power sub-line is connected to one second power line.

In an exemplary embodiment of the present disclosure, the plurality of pixel driving circuits in the same pixel unit form a pixel driving circuit group, and the plurality of light emitting units in the same pixel unit form a light emitting unit group; the light emitting unit groups are evenly distributed at equal intervals and at least a part of the pixel driving circuit groups are not evenly distributed at equal intervals.

In an exemplary embodiment of the present disclosure, a distance between two adjacent pixel driving circuit groups in the island region along the row direction is less than a distance between two adjacent pixel driving circuit groups in the bridge region along the row direction; a distance between two adjacent pixel driving circuit groups in the island region along the column direction is less than a distance between two adjacent pixel driving circuit groups in the bridge region along the column direction.

In an exemplary embodiment of the present disclosure, the pixel driving circuit includes a driving transistor, a switching transistor, and a capacitor; a first electrode of the driving transistor is connected to a power line, and a second electrode of the driving transistor is connected to the light emitting unit; a first electrode of the switching transistor is connected to a data line, a second electrode of the switching transistor is connected to a gate of the driving transistor, and a gate of the switching transistor is connected to a gate line; a first electrode of the capacitor is connected to the power line, and a second electrode of the capacitor is connected to the gate of the driving transistor; the display substrate further includes: a base substrate; an active layer, disposed on a side of the base substrate, where a partial structure of the active layer is configured to form a channel region of the driving transistor and a channel region of the switching transistor; a first gate layer, disposed on a side of the active layer facing away from the base substrate, where a partial structure of the first gate layer is configured to form the gate line, the gate of the driving transistor and the gate of the switching transistor, and the second electrode of the capacitor; a second gate layer, disposed on a side of the first gate layer facing away from the base substrate, where a partial structure of the second gate layer is configured to form the first electrode of the capacitor; a first source-drain layer, disposed on a side of the second gate layer facing away from the base substrate, a partial structure of the first source-drain layer is configured to form the data line and the power line.

In an exemplary embodiment of the present disclosure, the display substrate further includes: a base substrate; a second source-drain layer, disposed on a side of the base substrate; a first planarization layer disposed on a side of the second source-drain layer facing away from the base substrate; a first passivation layer, disposed on a side of the first planarization layer facing away from the base substrate, where at least one groove around the hollow aperture is defined on the first passivation layer, the groove runs through the first passivation layer and the first planarization layer; a barrier layer, disposed on a side of the first passivation layer facing away from the base substrate, where the barrier layer is filled in the groove to form a barrier dam, and a preset distance is provided between an orthographic projection of a side of the barrier dam furthest from the hollow aperture on the base substrate and an orthographic projection of the second source-drain layer on the base substrate.

In an exemplary embodiment of the present disclosure, the display substrate further includes: a base substrate; a second source-drain layer, disposed on a side of the base substrate; a first planarization layer disposed on a side of the second source-drain layer facing away from the base substrate; a first passivation layer, disposed on a side of the first planarization layer facing away from the base substrate; a second passivation layer, disposed on a side of the first passivation layer facing away from the base substrate, where the second passivation layer is defined with a venting hole running through the first passivation layer and the second passivation layer; an anode layer, disposed on a side of the second passivation layer facing away from the base substrate, where the anode layer includes a plurality of electrode portions, orthographic projections of the electrode portions on the base substrate do not overlap with an orthographic projection of the venting hole on the base substrate.

According to an aspect of the present disclosure, a display apparatus is provided and includes the above display substrate.

It should be noted that the above general description and the following detailed description are merely exemplary and explanatory and should not be construed as limiting of the present disclosure.

### BRIEF DESCRIPTION OF THE DRAWINGS

The drawings here are incorporated to the specification and constitute a part of the specification, show embodiments consistent with the present disclosure, and are configured together with the specification to explain principles of the present disclosure. Obviously, the drawings in the following description are only some embodiments of the present disclosure. For those skilled in the art, other drawings can be obtained based on these drawings without creative work.

FIG. 1 shows a structural diagram of an exemplary embodiment of a display substrate in the present disclosure;

FIG. 2 shows a partially enlarged view of a repeating unit A of the display substrate shown in FIG. 1;

FIG. 3 shows an equivalent circuit diagram of a pixel driving circuit in an exemplary embodiment;

FIG. 4 shows a structural layout of a pixel driving circuit in a display substrate of the present disclosure;

FIG. 5 shows a structural layout of an active layer in FIG. 4;

FIG. 6 shows a structural layout of a first gate layer in FIG. 4;

FIG. 7 shows a structural layout of a second gate layer in FIG. 4;

FIG. 8 shows a structural layout of a first source-drain layer in FIG. 4;

FIG. 9 shows a structural layout of a second source-drain layer in FIG. 4;

FIG. 10 shows a structural layout of an anode layer in FIG. 4;

FIG. 11 shows a structural layout of an active layer and a first gate layer in FIG. 4;

FIG. 12 shows a structural layout of an active layer, a first gate layer, and a second gate layer in FIG. 4;

FIG. 13 shows a structural layout of an active layer, a first gate layer, a second gate layer, and a first source-drain layer in FIG. 4;

FIG. 14 shows a structural layout of an active layer, a first gate layer, a second gate layer, a first source-drain layer, and a second source-drain layer in FIG. 4;

FIG. 15 shows a sectional view along a dashed line BB in the display substrate shown in FIG. 4;

FIG. 16 shows a structural layout of a repeating unit A in FIG. 1;

FIG. 17 shows a structural layout of an active layer in FIG. 16;

FIG. 18 shows a structural layout of a first gate layer in FIG. 16;

FIG. 19 shows a structural layout of a second gate layer in FIG. 16;

FIG. 20 shows a structural layout of a first source-drain layer in FIG. 16;

FIG. 21 shows a structural layout of a second source-drain layer in FIG. 16;

FIG. 22 shows a structural version of an anode layer in FIG. 16;

FIG. 23 shows a structural layout of an active layer and a first gate layer in FIG. 16;

FIG. 24 shows a structural layout of an active layer, a first gate layer, and a second gate layer in FIG. 16;

FIG. 25 shows a structural layout of an active layer, a first gate layer, a second gate layer, and a first source-drain layer in FIG. 16;

FIG. 26 shows a structural layout of an active layer, a first gate layer, a second gate layer, a first source-drain layer, and a second source-drain layer in FIG. 16;

FIG. 27 shows a partially enlarged view of a localized region A1 in FIG. 16;

FIG. 28 shows a structural layout of an active layer in FIG. 27;

FIG. 29 shows a structural layout of a first gate layer in FIG. 27;

FIG. 30 shows a structural layout of a second gate layer in FIG. 27;

FIG. 31 shows a structural layout of a first source-drain layer in FIG. 27;

FIG. 32 shows a structural layout of a second source-drain layer in FIG. 27,

FIG. 33 shows a structural layout of an anode layer in FIG. 27;

FIG. 34 shows a structural layout of an active layer and a first gate layer in FIG. 27;

FIG. 35 shows a structural layout of an active layer, a first gate layer, and a second gate layer in FIG. 27;

FIG. 36 shows a structural layout of an active layer, a first gate layer, a second gate layer, and a first source-drain layer in FIG. 27;

FIG. 37 shows a structural layout of an active layer, a first gate layer, a second gate layer, a first source-drain layer, and a second source-drain layer in FIG. 27;

FIG. 38 shows a structural layout of a pixel defining layer in FIG. 16;

FIG. 39 shows a structural layout of a pixel defining layer and an anode layer in FIG. 16;

FIG. 40 shows a partial sectional view along a dashed line CC in FIG. 27;

FIG. 41 shows a structural layout of a first passivation layer, a second passivation layer, and an anode layer in FIG. 16.

### DETAILED DESCRIPTION

Embodiments will now be described more fully with reference to the drawings. However, the embodiments may be implemented in a variety of forms and should not be construed as being limited to examples set forth herein; rather, these embodiments are provided such that the present disclosure will be more complete and full so as to convey the idea of the embodiments to those skilled in the art. The same reference numerals in the drawings denote the same or similar structures, and the repeated description thereof will be omitted.

The terms “one”, “a” and “the” are configured to indicate that there are one or more elements/components or the like; and the terms “include” and “have” are configured to indicate an open meaning of including and means that there can be additional elements/components/etc. in addition to the listed elements/components/etc ..

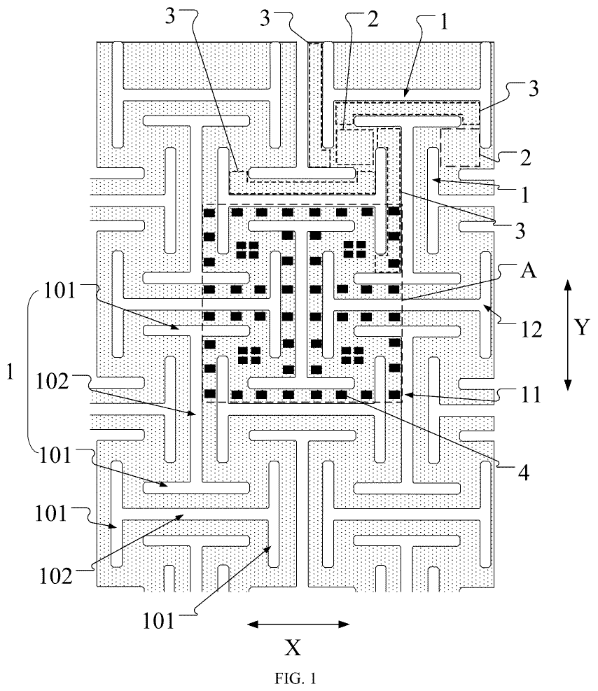

The exemplary embodiment provides a display substrate, as shown in FIG. 1, which shows a structural diagram of an exemplary embodiment of a display substrate in the present disclosure, the display substrate may include a plurality of hollow apertures 1, a plurality of island regions 2 separated by the plurality of hollow apertures 1 and bridge regions 3 connected between the island regions 2, and the display substrate further includes: a plurality of pixel units 4, and the plurality of pixel units 4 may be provided in the island regions 2 and the bridge regions 3.

In the exemplary embodiment, the display substrate is provided with the pixel unit 4 at both the island region and the bridge region, such that the display substrate may have a high resolution.

It should be noted that, as shown in FIG. 1, the exemplary embodiment only illustrates the pixel unit 4 in the repeating unit A of the display substrate, and it should be understood that the pixel unit 4 is also provided in other bridge and island regions of the display substrate, and the pixel unit 4 in the other regions of the display substrate may be distributed in the same manner as the pixel unit 4 in the repeating unit A.

In the exemplary embodiment, as shown in FIG. 1, the hollow aperture 1 may be in I-shape and the I-shaped hollow aperture 1 may include: two first strip-shaped apertures 101 opposite to each other, and a second strip-shaped aperture 102 connected between the two first strip-shaped apertures 101. The plurality of hollow apertures 1 may include a plurality of first hollow apertures 11 distributed in rows and columns and a plurality of second hollow apertures 12 distributed in rows and columns, the second strip-shaped aperture 102 of the first hollow aperture 11 extends along a column direction Y and the second strip-shaped aperture 102 of the second hollow aperture 12 extends along the row direction X. The second hollow aperture 12 is disposed between two adjacent first hollow apertures 11 in the row direction X, and the first hollow aperture 11 is disposed between two adjacent second hollow apertures 12 in the column direction Y. The first hollow apertures 11 in adjacent columns and in adjacent rows are staggered in the column direction Y, the second hollow apertures 12 in adjacent rows and in adjacent columns are staggered in the row direction X. The first hollow apertures 11 in adjacent columns and in adjacent rows are staggered in the column direction Y, which may be understood as that, regions covered by the movement of the first hollow apertures 11 moving in adjacent columns and in adjacent rows along the row direction X are partially intersected; and the second hollow apertures 12 in adjacent rows and in adjacent columns are staggered in the row direction X, which may be understood as that, regions covered by the movement of the second hollow apertures 12 moving in adjacent columns and in adjacent rows along the column direction Y are partially intersected. The row direction X and the column direction Y may intersect, for example, the row direction X and the column direction Y are perpendicular, and the pixel driving circuit in the display substrate may be driven row by row. As shown in FIG. 1, the first strip-shaped apertures 101 of two first hollow apertures 11 arranged in a staggered manner and the first strip-shaped apertures 101 of two second hollow apertures 12 arranged in a staggered manner form the island region 2. The second strip-shaped aperture 102 of the first hollow aperture 11 and the first strip-shaped aperture 101 of the second hollow aperture 12 may form a partial structure of a certain bridge region 3, and the first strip-shaped aperture 101 of the first hollow aperture 11 and the second strip-shaped aperture 102 of the second hollow aperture 12 may form a partial structure of a certain bridge region 3. As shown in FIG. 1, in an exemplary embodiment, the plurality of island regions 2 may be distributed in rows and columns, and each island region 2 is connected to four bridge regions 3, and each island region 2 may be connected to the four island regions 2 adjacent to it in the row and column direction, respectively, through the four bridge regions 3.

It should be understood that in some exemplary embodiments, the hollow aperture may also be of other shapes, e.g., the hollow aperture may also be in T shape and the like.

In an exemplary embodiment, as shown in FIG. 1, both the first strip-shaped aperture 101 and the second strip-shaped aperture 102 extend along a straight line, and it should be understood that in some exemplary embodiments, the first strip-shaped aperture 101 and the second strip-shaped aperture 102 may also extend along a curve or a fold line.

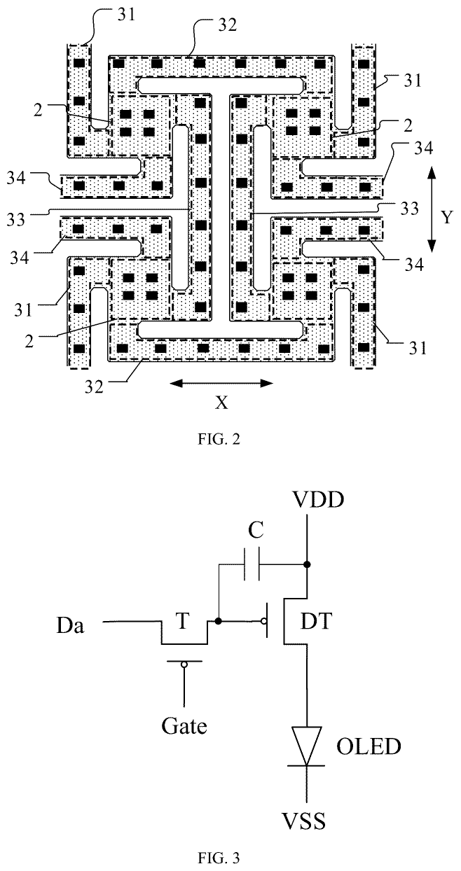

As shown in FIG. 2, FIG. 2 is a partially enlarged view of a repeating unit A of the display substrate shown in FIG. 1. The four bridge regions connected to the same island region 2 may include a first bridge region 31, a second bridge region 32, a third bridge region 33, and a fourth bridge region 34, a partial region of the first bridge region 31 and the third bridge region 33 are disposed between the second strip-shaped aperture 102 of the first hollow aperture 11 and the first strip-shaped aperture 101 of the second hollow aperture 12, and a partial region of the second bridge region 32 and the fourth bridge region 34 are disposed between the first strip-shaped aperture 101 of the first hollow aperture 11 and the second strip-shaped aperture 102 of the second hollow aperture 12.

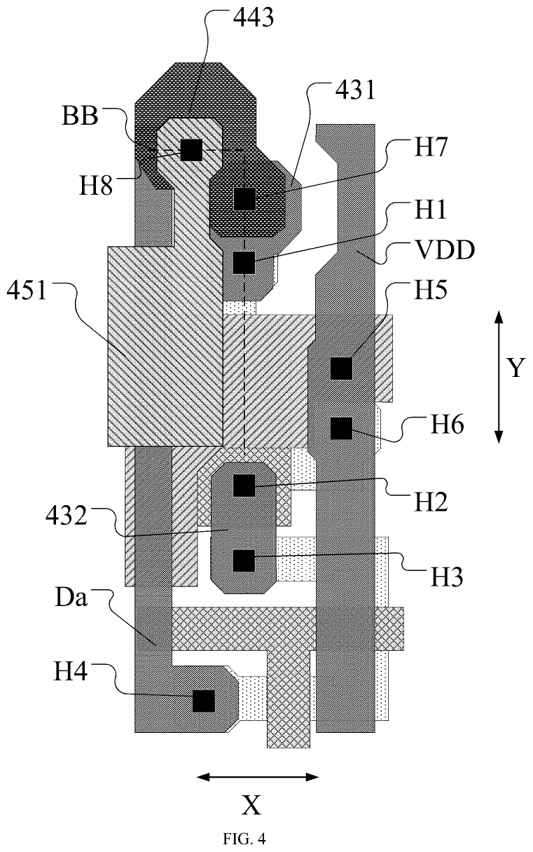

In the exemplary embodiment, each pixel unit may include three pixel driving circuits and three light emitting units in one-to-one correspondence with the pixel driving circuits, as shown in FIG. 3, and FIG. 3 is an equivalent circuit diagram of a pixel driving circuits in an exemplary embodiment. The pixel driving circuit may include a switching transistor T, a driving transistor DT, and a capacitor C. A first electrode of the driving transistor DT is connected to a first power supply terminal VDD, a second electrode of the driving transistor DT is connected to the light emitting unit OLED, and the other terminal of the light emitting unit OLED is connected to a second power supply terminal VSS; a first electrode of the switching transistor T is connected to a data signal terminal Da, and a second electrode of the switching transistor T is connected to a gate of the driving transistor DT, a gate of the switching transistor T is connected to a gate driving signal terminal Gate; a capacitor C is connected between the gate of the driving transistor DT and the first power supply terminal VDD. The driving transistor and the switching transistor may be P-type transistors. It should be understood that in some exemplary embodiments, each pixel unit may also include other numbers of pixel driving circuits, and the pixel driving circuit may be of another structure.

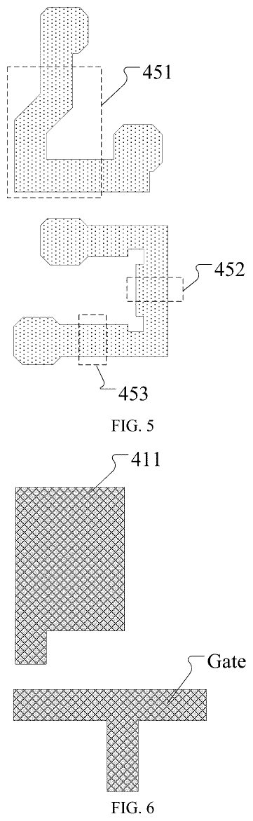

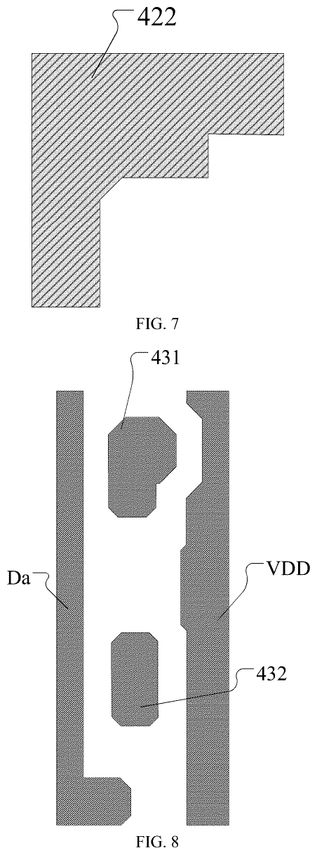

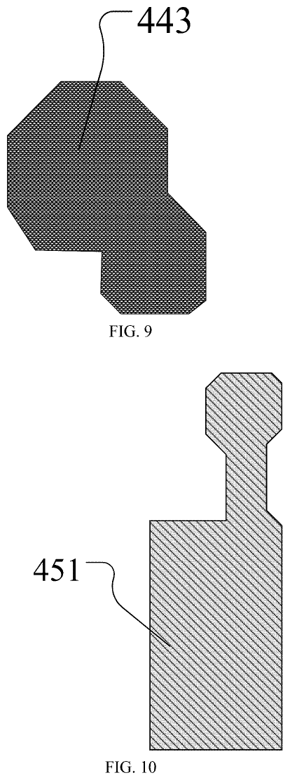

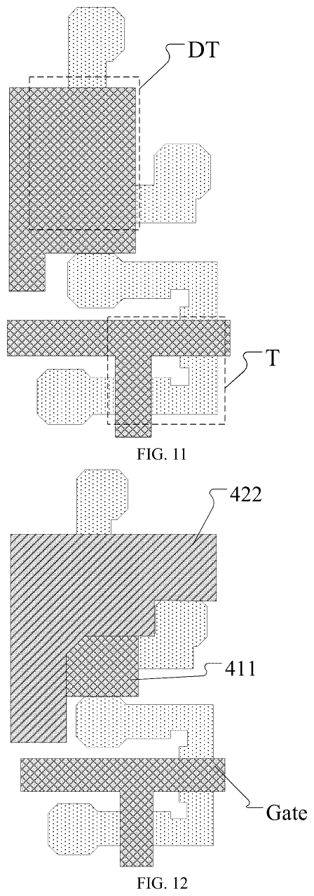

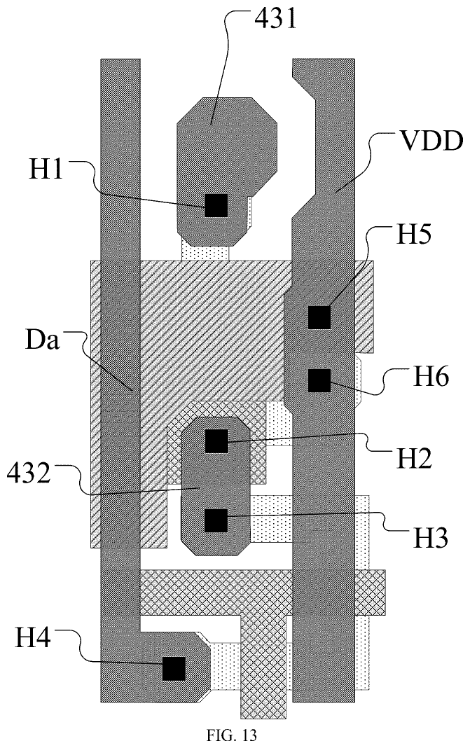

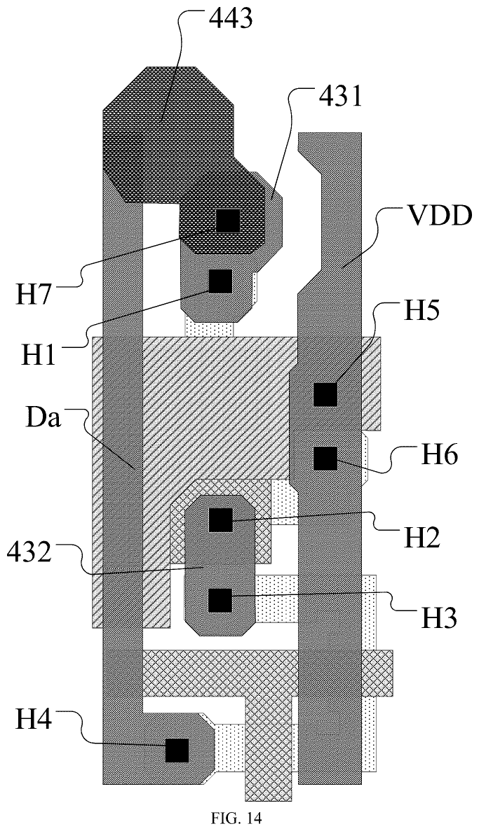

In the exemplary embodiment, the display substrate may include a base substrate, an active layer, a first gate layer, a second gate layer, a first source-drain layer, a second source-drain layer, and an anode layer stacked in sequence. An insulating layer may be provided between the above adjacent structural layers. As shown in FIGS. 4-14, FIG. 4 shows a structural layout of a pixel driving circuit in a display substrate of the present disclosure, FIG. 5 shows a structural layout of an active layer in FIG. 4, FIG. 6 shows a structural layout of a first gate layer in FIG. 4, FIG. 7 shows a structural layout of a second gate layer in FIG. 4, FIG. 8 shows a structural layout of a first source drain layer in FIG. 4, FIG. 9 shows a structural layout of a second source drain layer in FIG. 4, FIG. 10 shows a structural layout of an anode layer in FIG. 4, FIG. 11 shows a structural layout of an active layer and a first gate layer in FIG. 4, FIG. 12 shows a structural layout of an active layer, a first gate layer, and a second gate layer in FIG. 4, FIG. 13 shows a structural layout of an active layer, a first gate layer, a second gate layer, and a first source-drain layer in FIG. 4, and FIG. 14 shows a structural layout of an active layer, a first gate layer, a second gate layer, a first source-drain layer, and a second source-drain layer in FIG. 4.

As shown in FIGS. 4, 5, and 11, the active layer may include a first active portion 451, a second active portion 452, and a third active portion 453, the first active portion 451 may be configured to form a channel region of the driving transistor DT, and the second active portion 452 and the third active portion 453 may be configured to form two channel regions of the switching transistor T. The active layer may be formed from a polycrystalline silicon material, and accordingly, the driving transistor DT, and the switching transistor T may be low temperature polycrystalline silicon transistors. It should be understood that in some exemplary embodiments, the active layer may also be formed from other semiconductor materials, for example, the active layer may be formed from an oxide semiconductor.

As shown in FIGS. 4, 6, and 11, the first gate layer may include a first conductor portion 411 and a gate line segment Gate. The gate line segment Gate may be configured to provide the gate driving signal terminal in FIG. 3, an orthographic projection of the gate line segment Gate on the base substrate may cover orthographic projections of the second active portion 452 and the third active portion 453 on the base substrate, and a partial structure of the gate line segment Gate may be configured to form the gate of the switching transistor. An orthographic projection of the first conductor portion 411 on the base substrate may cover an orthographic projection of the first active section 451 on the base substrate, and the first conductor portion 411 may be configured to form the gate of the driving transistor DT and the second electrode of the capacitor. The display substrate perform a conductor treatment on the active layer by using the first gate layer as a mask, i.e., a region covered by the first gate layer forms a channel region of the transistor, and a region not covered by the first gate layer may form a conductor structure.

As shown in FIGS. 4, 7, 12, the second gate layer may include a second conductor portion 422, and an orthographic projection of the second conductor portion 422 on the base substrate may at least partially overlap with the orthographic projection of the first conductor portion 411 on the base substrate. The second conductor portion 422 may be configured to form the first electrode of the capacitor C.

As shown in FIGS. 4, 8, and 13, the first source-drain layer may include a power line segment VDD, a data line segment Da, a first bridging portion 431, and a second bridging portion 432. The power line segment VDD may be configured to provide the first power supply terminal in FIG. 3, the power line segment VDD may be connected to the second conductor portion 422 through a via hole H5, and the power line segment VDD may be connected to the active layer on a side of the first active portion 451 through a via hole H6, so as to be connected to the first electrode of the capacitor C, the first electrode of the driving transistor DT, and the first power supply terminal. The data line segment Da may be configured to provide the data signal terminal in FIG. 3, and the data line segment Da may be connected to the active layer on a side of the third active portion 453 away from the second active portion 452 through a via hole H4, so as to be connected to the data signal terminal and the first electrode of the switching transistor. The first bridging portion 431 may be connected to the active layer on the other side of the first active portion 451 through a via hole H1, so as to be connected to the second electrode of the driving transistor. The second bridging portion 432 may be connected to the first conductor portion 411 through a via hole H2 and the active layer on a side of the second active portion 452 away from the third active portion 453 through a via hole H3, so as to be connected to the gate of the driving transistor and the second electrode of the switching transistor.

As shown in FIGS. 4, 8, and 14, the second source-drain layer may include a third bridging portion 443, and the third bridging portion 443 may be connected to the first bridging portion 431 through a via hole H7.

As shown in FIGS. 4, 9, the anode layer may include an electrode portion 461, and the electrode portion 461 may be connected to the third bridging portion 443 through a via hole H8. The electrode portion 461 may form an electrode of the light emitting unit.

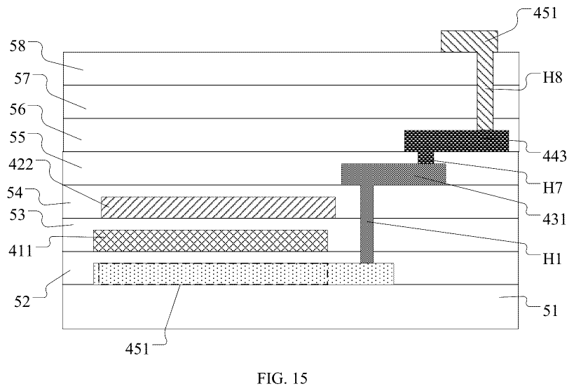

As shown in FIG. 15, FIG. 15 is a sectional view along a dashed line BB in the display substrate shown in FIG. 4, the display substrate may further include a first insulating layer 52, a second insulating layer 53, a dielectric layer 54, a second planarization layer 55, a first planarization layer 56, a first passivation layer 57, and a second passivation layer 58. The base substrate 51, the active layer, the first insulating layer 52, the first gate layer, the second insulating layer 53, the second gate layer, the dielectric layer 54, the first source-drain layer, the second planarization layer 55, the second source-drain layer, the first planarization layer 56, the first passivation layer 57, the second passivation layer 58, and the anode layer are stacked in sequence. The first insulating layer 52 and the second insulating layer 53 may be a silicon oxide layer; the dielectric layer 54, the first passivation layer 57 and the second passivation layer 58 may be a silicon nitride layer; materials of the first planarization layer 56 and the second planarization layer 55 may be an organic material, such as a polyimide (PI), polyethylene terephthalate (PET), polyethylene naphthalate (PEN), silicone-to-glass bonding structure (SOG), and other materials. The base substrate 51 may be a flexible base substrate, and may include a polyimide layer, and materials of the first gate layer and the second gate layer may be one of molybdenum, aluminum, copper, titanium, niobium or an alloy, or a molybdenum/titanium alloy or a stacked layer and the like. Materials of the first source-drain layer and the second source-drain layer may include a metal material, for example, may be one of molybdenum, aluminum, copper, titanium, niobium, or an alloy, or a molybdenum/titanium alloy or a stacked layer, and the like, or may be a titanium/aluminum/titanium stacked layer. In addition, the display substrate may also include a pixel defining layer disposed on a side of the anode layer facing away from the base substrate.

In an exemplary embodiment, the hollow aperture may run through the base substrate 51, the active layer, the first insulating layer 52, the first gate layer, the second insulating layer 53, the second gate layer, the dielectric layer 54, the first source-drain layer, the second planarization layer 55, the second source-drain layer, the first planarization layer 56, the first passivation layer 57, the second passivation layer 58, the anode layer, and the pixel dielectric layer. Where any one of the dielectric layer 54, the first source-drain layer, the second planarization layer 55, the second source-drain layer, the first planarization layer 56, the first passivation layer 57, the second passivation layer 58, the anode layer, and the pixel dielectric layer is formed through a patterning process, the region of the hollow aperture may be etched through the base substrate by an etching process, and the process may avoid residuals of the above respective film layers within the hollow apertures.

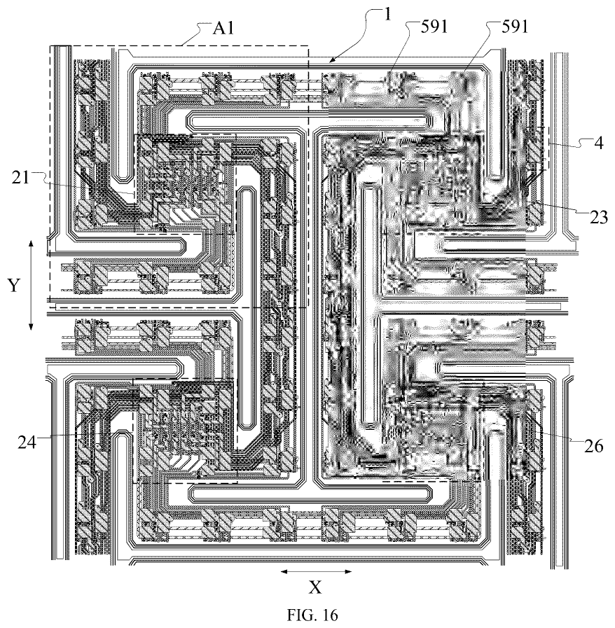

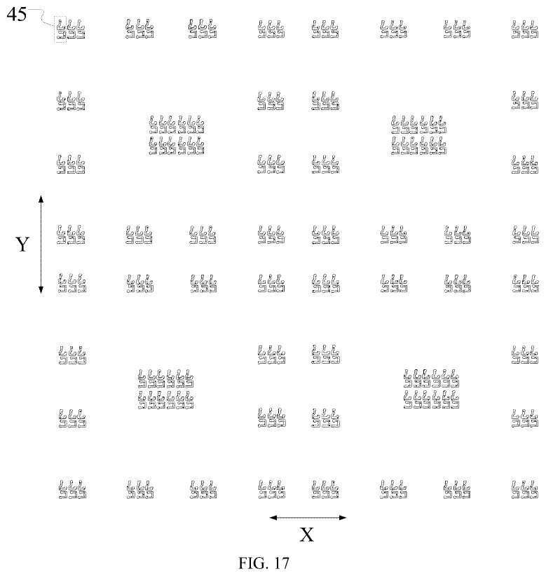

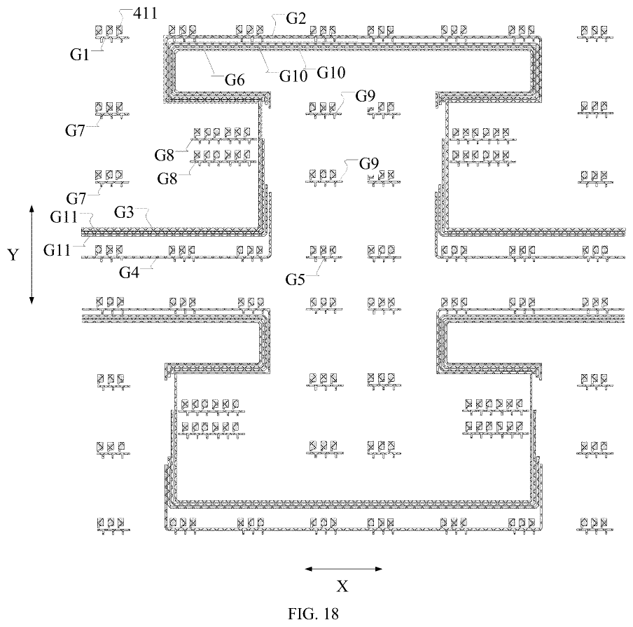

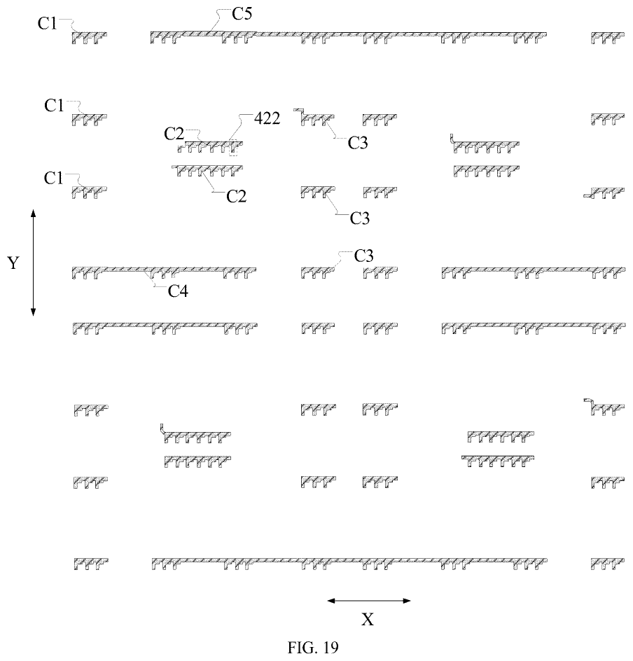

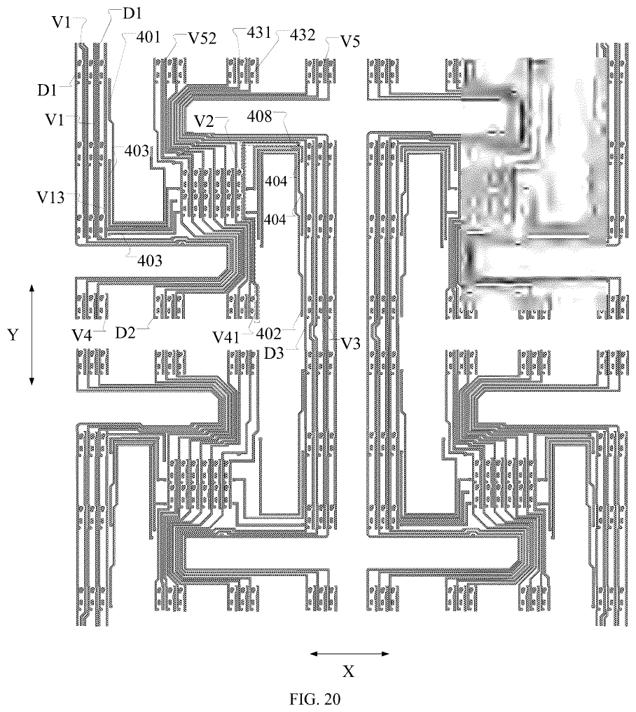

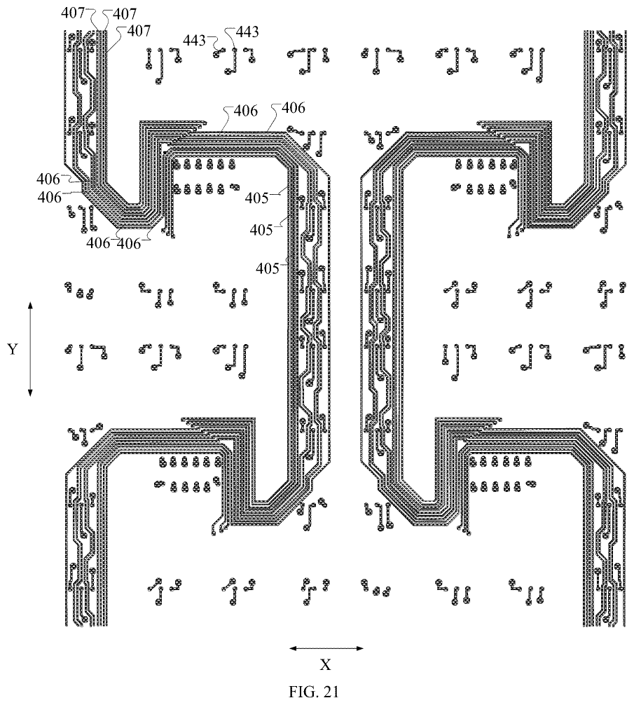

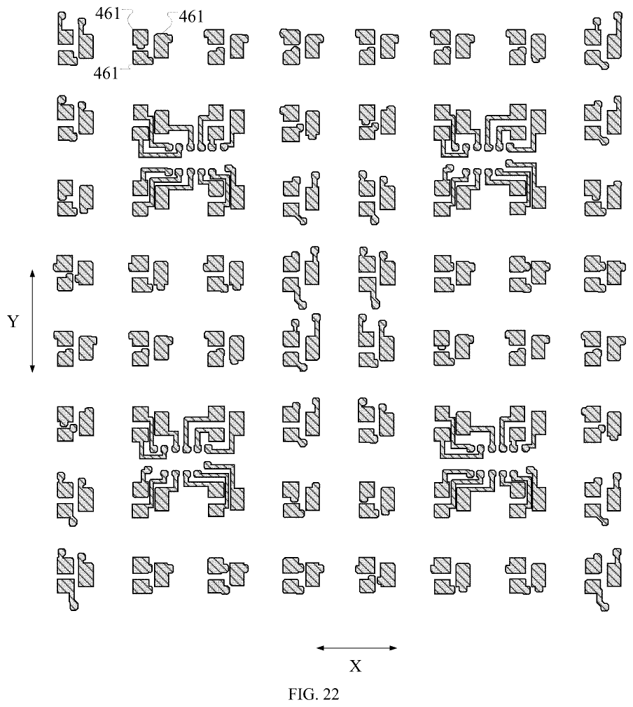

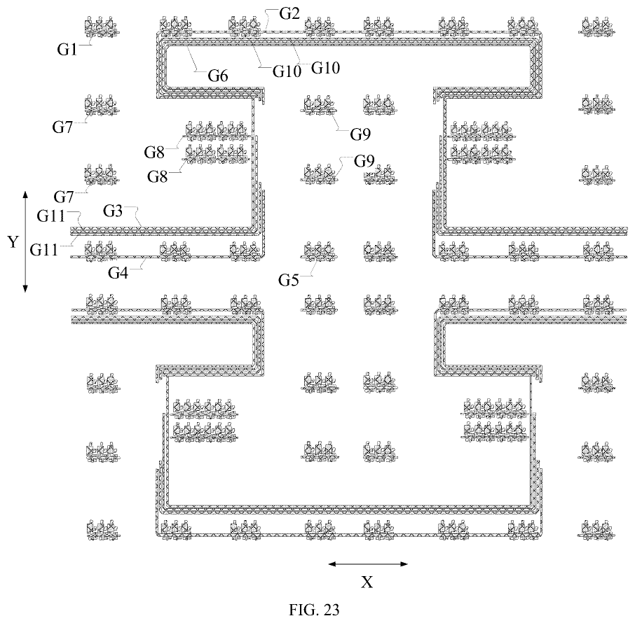

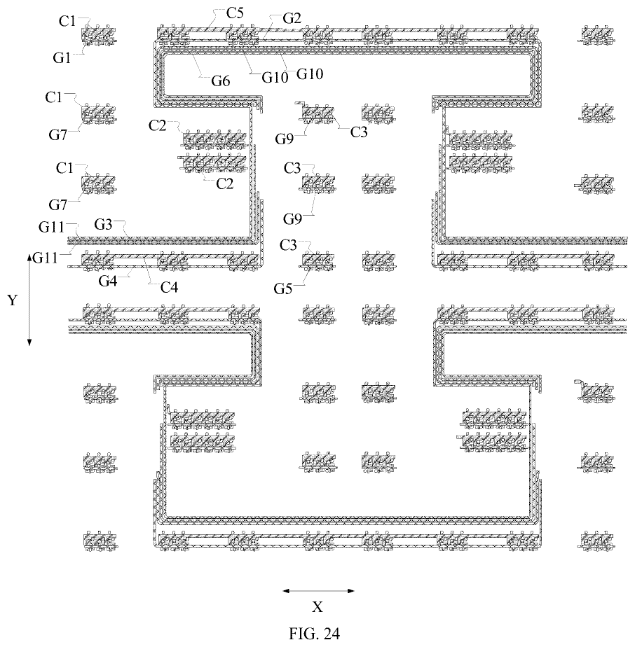

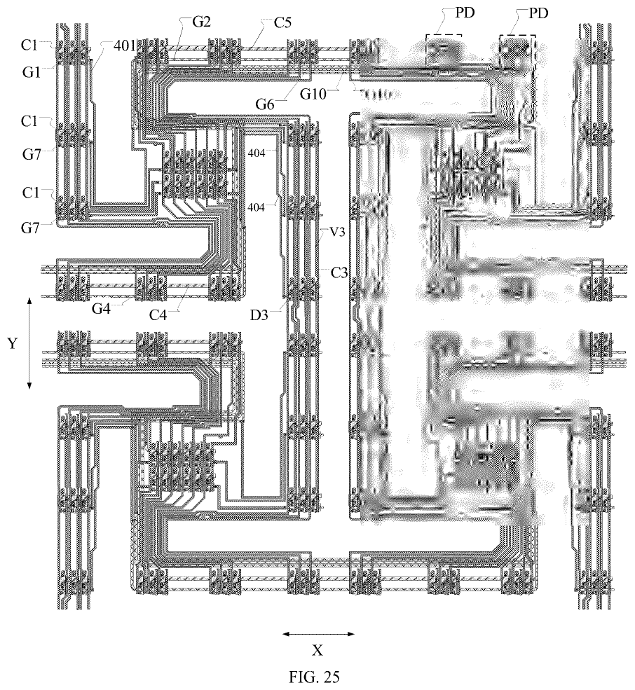

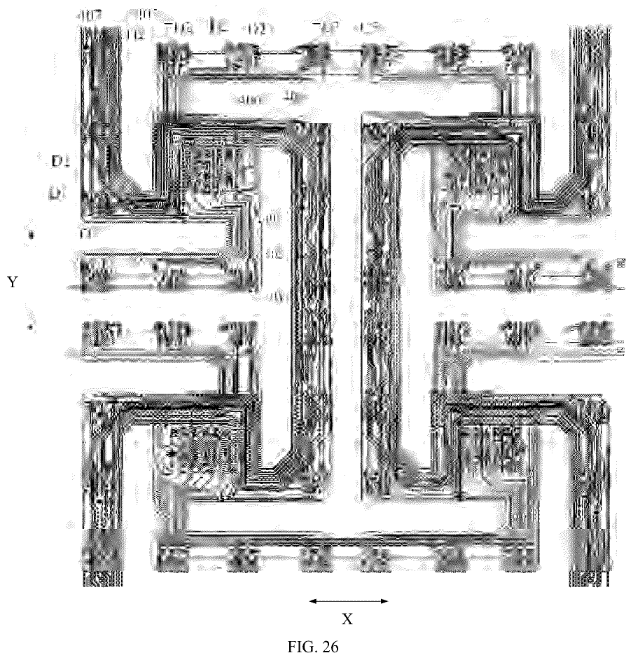

As shown in FIGS. 16-26, FIG. 16 shows a structural layout of a repeating unit A in FIG. 1, FIG. 17 shows a structural layout of an active layer in FIG. 16, FIG. 18 shows a structural layout of a first gate layer in FIG. 16, FIG. 19 shows a structural layout of a second gate layer in FIG. 16, FIG. 20 shows a structural layout of a first source-drainage layer in FIG. 16, FIG. 21 shows a structural layout of a second source-drainage layer in FIG. 16, and FIG. 22 shows a structural layout of an anode layer, FIG. 23 shows a structural layout of an active layer and a first gate layer in FIG. 16, FIG. 24 shows a structural layout of an active layer, a first gate layer, and a second gate layer in FIG. 16, FIG. 25 shows a structural layout of an active layer, a first gate layer, a second gate layer, and a first source-drain layer in FIG. 16, and FIG. 26 shows a structural layout of an active layer, a first gate layer, a second gate layer, a first source-drain layer, and a second source-drain layer in FIG. 16.

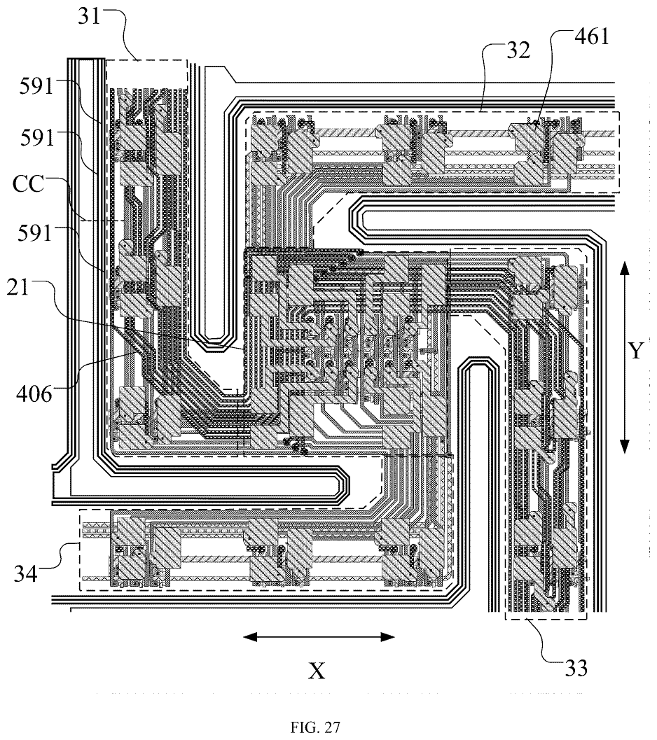

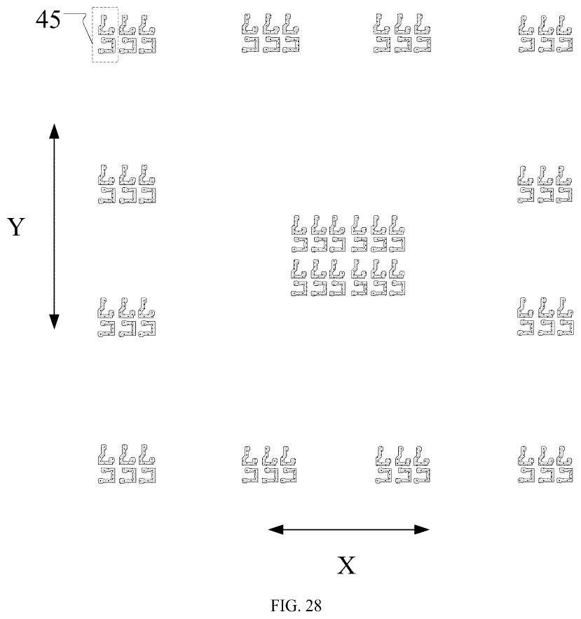

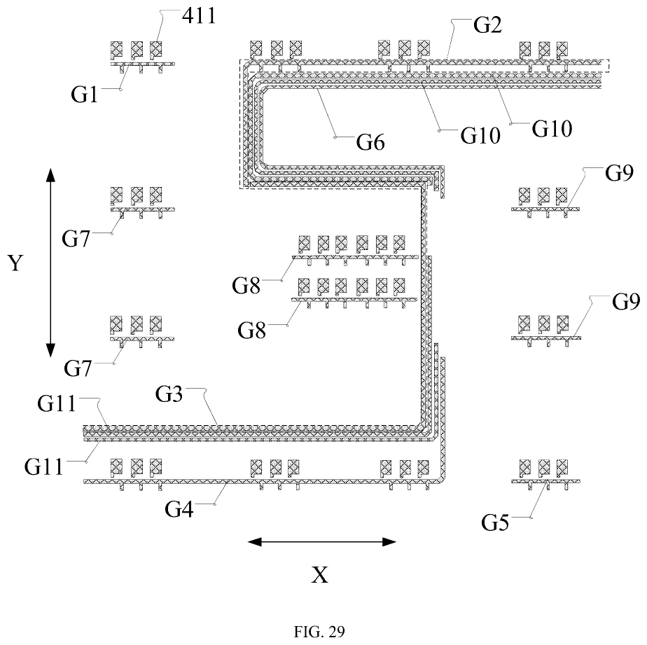

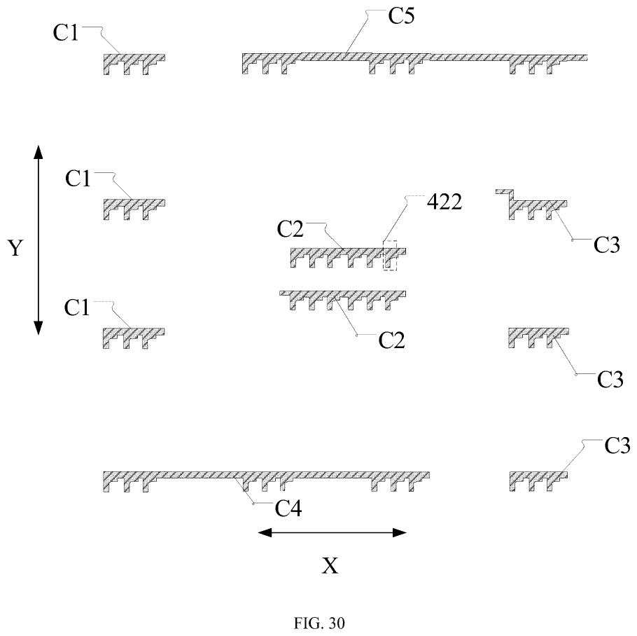

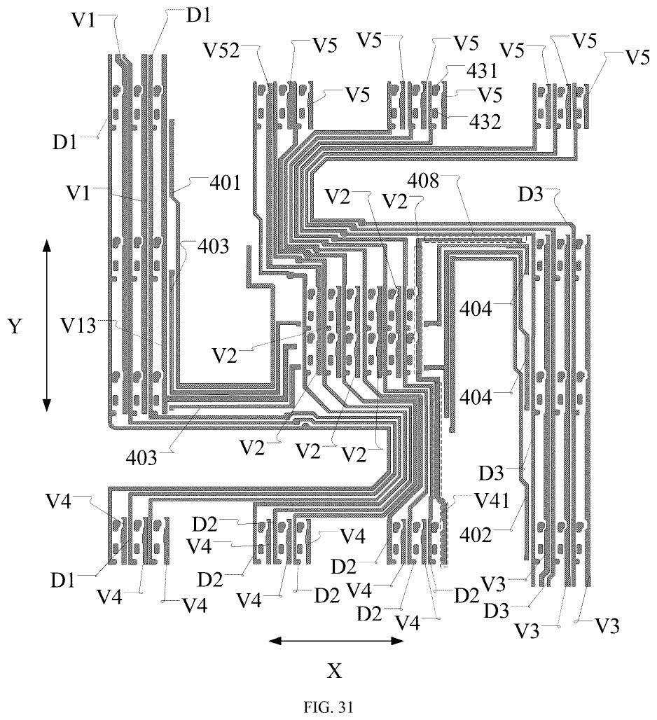

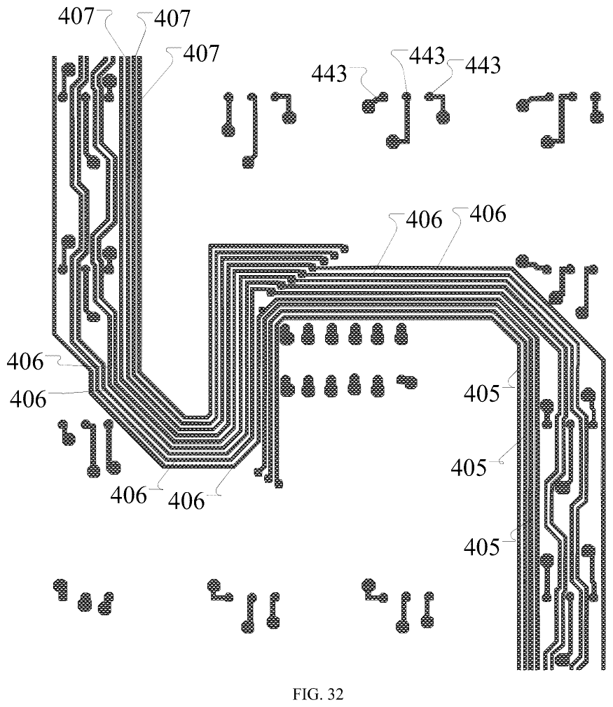

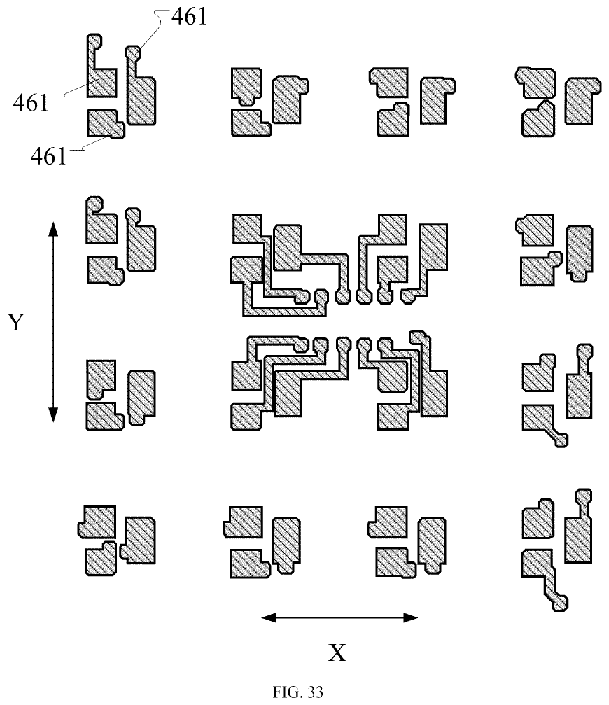

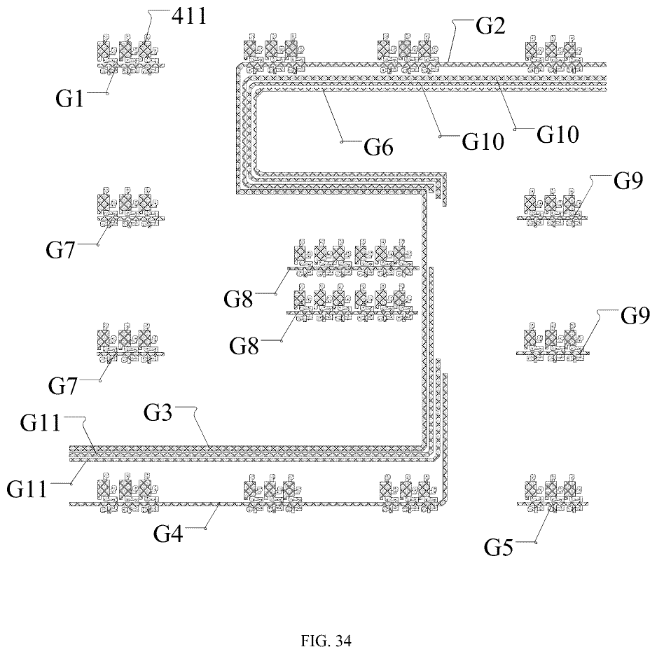

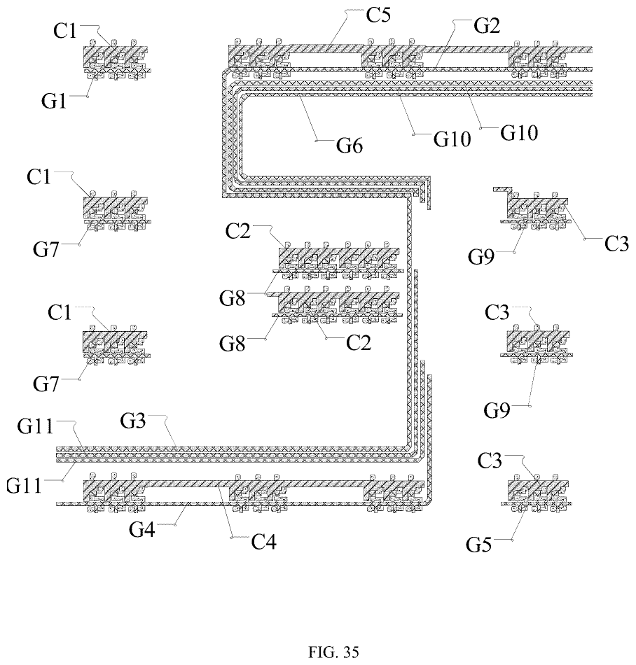

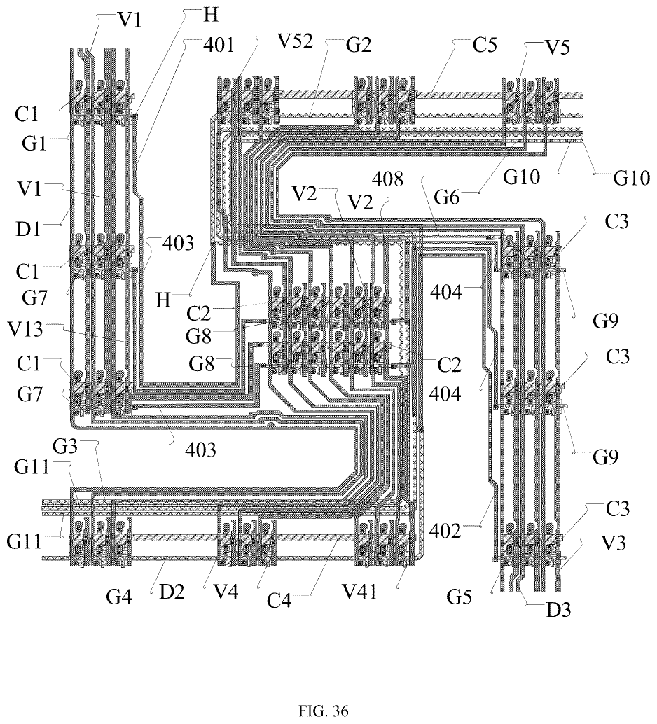

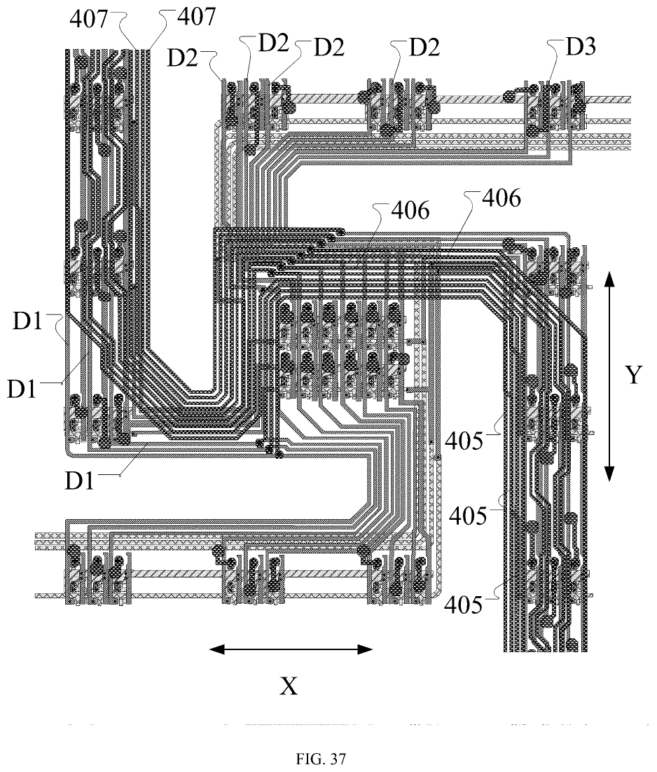

As shown in FIGS. 27-37, FIG. 27 shows a partially enlarged view of a localized region A1 in FIG. 16; FIG. 28 shows a structural layout of an active layer in FIG. 27; FIG. 29 shows a structural layout of a first gate layer in FIG. 27; FIG. 30 shows a structural layout of a second gate layer in FIG. 27; FIG. 31 shows a structural layout of a first source-drain layer in FIG. 27; FIG. 32 shows a structural layout of a second source-drain layer in FIG. 27, FIG. 33 shows a structural layout of an anode layer in FIG. 27; FIG. 34 shows a structural layout of an active layer and a first gate layer in FIG. 27; FIG. 35 shows a structural layout of an active layer, a first gate layer, and a second gate layer in FIG. 27; FIG. 36 shows a structural layout of an active layer, a first gate layer, a second gate layer, and a first source-drain layer in FIG. 27; FIG. 37 shows a structural layout of an active layer, a first gate layer, a second gate layer, a first source-drain layer and a second source-drain layer in FIG. 27;

As shown in FIG. 16, the repeating units A may be provided mirror-symmetrically in the row direction, and the repeating units may be provided mirror-symmetrically in the column direction. The repeating unit may include four island regions, the four island regions including a first island region 21, a third island region 23, a fourth island region 24, and a sixth island region 26 distributed in an array. The first island region 21 and the third island region 23 are provided adjacent to each other in the row direction X, and the first island region 21 and the fourth island region 24 are provided adjacent to each other in the column direction Y. The first island region 21 is connected to the third island region 23 through a second bridge region, and the first island region 21 is connected to the fourth island region 24 through a fourth bridge region.

As shown in FIGS. 16, 17, 23, 27, 28 and 34, the active layer in FIG. 16 includes a plurality of repeating structures 45 shown in FIG. 5. The repeating structures 45 are provided in one-to-one correspondence with the pixel driving circuits.

As shown in FIGS. 16, 18, 23, 27, 29 and 34, the first gate layer in FIG. 16 includes a plurality of first conductor portions 411 in FIG. 6, the first conductor portion 411 is provided in one-to-one correspondence with the pixel driving circuit, to form the gate of the driving transistor and the second electrode of the capacitor. In addition, the first gate layer further includes a first gate line G1, a second gate line G2, the first gate line G1 is disposed on the first bridge region 31 and is connected to the pixel driving circuit disposed in the first bridge region 31 of the same driving row, and the second gate line G2 is disposed on the second bridge region 32 and is connected to the pixel driving circuit disposed in the second bridge region 32 of the same driving row; the first bridge region 31 where the first gate line G1 is disposed and the second bridge region 32 where the second gate line G2 is disposed are connected to the same island region, and the pixel driving circuit connected to the first gate line G1 and the pixel driving circuit connected to the second gate line G2 are disposed on the same driving row. The plurality of pixel driving circuits being disposed on the same driving row refers to that the plurality of pixel driving circuits are driven by the same gate driving signal. The first gate line G1, the second gate line G2 may both be formed by interconnecting the gate line segments Gate in FIG. 4. As shown in FIGS. 16, 20, 25, 27, 31 and 36, the first source-drain layer may include: a first connection line 401, a partial structure of the first connection line 401 is disposed on the first bridge region 31 where the first gate line G1 is disposed, and the first connection line 401 is connected to the first gate line G1 and the second gate line G2, respectively, through a via hole H. The arrangement may connect the first connection line 401 with the first gate line G1 and the second gate line G2, such that the pixel driving circuit connected to the first gate line G1 and the pixel driving circuit connected to the second gate line G2 are driven by the same gate driving signal. It should be noted that in an exemplary embodiment, the via hole His indicated by a black square, and only some locations of the via holes are labeled in the exemplary embodiment.

As shown in FIGS. 16, 18, 23, 27, 29 and 34, the first gate layer may further include: a third gate line G3, a partial structure of the third gate line G3 is disposed on the fourth bridge region 34 and an island region connected to the fourth bridge region 34. The fourth bridge region 34 where the third gate line G3 is disposed is connected to the same island region with the second bridge region 32 where the second gate line G2 is disposed. The display substrate may further include a second island region (not shown), the second island region is disposed on the same row as the first island region 21 and the second island region is disposed on a side of the first island region 21 away from the third island region 23. The first island region 21 and the second island region may be connected through the fourth bridge region 34, and the third gate line G3 disposed in the fourth bridge region 34 may be connected to the second gate line G2 corresponding to the first island region 21 and the second gate line G2 corresponding to the second island region. The second bridge region where the second gate line G2 corresponding to the first island region 21 is disposed is connected to the first island region, and the second bridge region where the second gate line corresponding to the second island region is disposed is connected to the second island region. Through the above arrangement, the pixel driving circuit in the second bridge region connected to the first island region 21 and the pixel driving circuit in the second bridge region connected to the second island region may be driven by the same gate driving signal.

As shown in FIGS. 16, 18, 23, 27, 29 and 34, the first gate layer may further include: a fourth gate line G4, a fifth gate line G5, the fourth gate line G4 is disposed on the fourth bridge region 34 and is connected to the pixel driving circuit disposed in the fourth bridge region 34 of the same driving row; the fifth gate line G5 is disposed on the third bridge region 33 and is connected to the pixel driving circuit disposed in the third bridge region 33 of the same driving row, and the pixel driving circuit connected to the fourth gate line G4 and the pixel driving circuit connected to the fifth gate line G5 are disposed on the same driving row. The fourth gate line G4 and the fifth gate line G5 may be formed by interconnecting the gate line segments Gate in FIG. 4. As shown in FIGS. 16, 20, 25, 27, 31 and 36, the first source-drain layer may further include: a second connection line 402, a partial structure of the second connection line 402 is disposed on the third bridge region 33 where the fifth gate line G5 is disposed, and an island region connected to the third bridge region. The second connection line 402 is connected to the fourth gate line G4 and the fifth gate line G5, respectively, through a via hole. Through the above arrangement, the pixel driving circuits connected to the fourth gate line G4 and the fifth gate line G5 may be driven by the same gate driving signal.

As shown in FIGS. 16, 18, 23, 27, 29 and 34, the first gate layer may further include: a sixth gate line G6, a partial structure of the sixth gate line G6 may be disposed on the second bridge region 32 and an island region connected to the second bridge region 32. The second bridge region 32 where the sixth gate line G6 is disposed is connected to the same island region with the fourth bridge region 34 where the fourth gate line G4 is disposed. The first island region 21 and the third island region 23 may be connected through second bridge region 32, and the sixth gate line G6 disposed in the second bridge region 32 may be connected to the fourth gate line G4 corresponding to the first island region 21 and the fourth gate line G4 corresponding to the third island region 23. As shown in FIG. 36, in an exemplary embodiment, the sixth gate line G6 may be connected to the the fourth gate line G4 through the second connection line 402, and the fourth bridge region 34 where the fourth gate line G4 corresponding to the first island region 21 is disposed is connected to the first island region 21, and the fourth bridge region 34 where the fourth gate line G4 corresponding to the third island region 23 is disposed is connected to the third island region 23. Through the above arrangement, the pixel driving circuit in the fourth bridge region connected to the first island region 21 and the pixel driving circuit in the fourth bridge region connected to the third island region 23 may be driven by the same gate driving signal.

As shown in FIGS. 16, 18, 23, 27, 29 and 34, the first gate layer may further include: a seventh gate line G7, an eighth gate line G8, the seventh gate line G7 is disposed on the first bridge region 31 and connected to the pixel driving circuit disposed in the first bridge region 31 of the same driving row, and the eighth gate line G8 is disposed on the island region and connected to the pixel driving circuit disposed in the island region of the same driving row, the island region where the eighth gate line G8 is disposed is connected to the first bridge region where the seventh gate line G7 is disposed, and the pixel driving circuit connected to the seventh gate line G7 and the pixel driving circuit connected to the eighth gate line G8 are disposed on the same driving row. The seventh gate line G7 and the eighth gate line G8 may be formed by interconnecting the gate line segments Gate in FIG. 4. As shown in FIGS. 16, 20, 25, 27, 31 and 36, the first source-drain layer may further include: a third connection line 403, a partial structure of the third connection line 403 may be disposed on the first bridge region 31 where the seventh gate line G7 is disposed, an island region connected to the first bridge region, and the third connection line 403 may be connected to the seventh gate line G7 and the eighth gate line G8, respectively, through a via hole. Through the above arrangement, the pixel driving circuits connected to the seventh gate line G7 and the eighth gate line G8 may be driven by the same gate driving signal.

As shown in FIGS. 16, 18, 23, 27, 29 and 34, the first gate layer may further include: a ninth gate line G9, the ninth gate line G9 is disposed on the third bridge region 33 and is connected to the pixel driving circuit disposed in the third bridge region 33 of the same driving row, the island region where the eighth gate line G8 is disposed is connected to the third bridge region 33 where the ninth gate line G9 is disposed, the pixel driving circuits connected to the ninth gate line G9 and the eighth gate line G8 are disposed on the same driving row. The ninth gate line G9 may be formed by interconnecting the gate line segments Gate in FIG. 4. As shown in FIGS. 16, 20, 25, 27, 31 and 36, the first source-drain layer may further include: a fourth connection line 404, a partial structure of the fourth connection line 404 is disposed on the third bridge region 33 where the ninth gate line G9 is disposed, an island region connected to the third bridge region, and the fourth connection line 404 is connected to the ninth gate line G9 and the eighth gate line G8, respectively, through a via hole. Through the above arrangement, the pixel driving circuits connected to the ninth gate line G9 and the eighth gate line G8 may be driven by the same gate driving signal.

As shown in FIGS. 16, 18, 23, 27, 29 and 34, the first gate layer may further include: a tenth gate line G10, an eleventh gate line G11, a partial structure of the tenth gate line G10 is disposed on the second bridge region and an island region connected to the second bridge region 32, and the second bridge region 32 where the tenth gate line G10 is disposed is connected to the island region where the eighth gate line G8 is disposed. A partial structure of the eleventh gate line G11 is disposed on the fourth bridge region and an island region connected to the fourth bridge region 34. The fourth bridge region 34 where the eleventh gate line G11 is disposed is connected to the island region where the eighth gate line G8 is disposed. The tenth gate line G10 disposed in the second bridge region 32 may be connected to the fourth connection line 404 corresponding to the first island region 21 and the fourth connection line 404 corresponding to the third island region 23 through a via hole; the eleventh gate line G11 disposed is the fourth bridge region 34 may be connected to the fourth connection line 404 corresponding to the first island region 21 and the fourth connection line 404 corresponding to the second island region connection line 404; the third bridge region where the fourth connection line 404 corresponding to the first island region 21 is disposed is connected to the first island region, the third bridge region where the fourth connection line corresponding to the third island region 23 is disposed is connected to the third island region, and the third bridge region where the fourth connection line corresponding to the second island region is disposed is connected to the second island region. Through the above arrangement, the eighth gate line corresponding to the first island region, the eighth gate line corresponding to the second island region, and the eighth gate line corresponding to the third island region may be connected to each other such that the pixel driving circuits disposed on the same driving row in the first island region, the second island region, and the third island region are driven by the same gate driving signal.

As shown in FIGS. 16, 19, 24, 27, 28 and 35, the second gate layer may include: a plurality of first electrode lines C1 and a plurality of second electrode line C2, the first electrode line C1 is disposed on the first bridge region 31, in the first bridge region 31, the first electrodes (the second conductor portion 422 in FIG. 7) of the capacitors disposed in the pixel driving circuit of the same driving row are connected to each other to form the first electrode line C1. The second electrode line C2 is disposed on the island region, in the island region, the first electrodes of the capacitors disposed in the pixel driving circuit of the same driving row are connected to each other to form the second electrode line C2, and the first bridge region 31 where the first electrode line C1 is disposed is connected to the island region where the second electrode line C2 is disposed. As shown in FIGS. 16, 20, 25, 27, 31, and 36, the first source-drain layer may further include: a plurality of first power lines V1, a plurality of second power lines V2, the plurality of first power lines VI are disposed on the first bridge region 31, the first power line V1 is connected to the pixel driving circuit disposed in the first bridge region 31 of the same driving column, and the power line segments VDD disposed in the pixel driving circuit of the same driving column in the first bridge region 31 may be connected to form a partial structure of the first power line V1. The second power line V2 is disposed on the island region, the island region where the second power line V2 is disposed is connected to the first bridge region 31 where the first power line V1 is disposed, and the second power line V2 is connected to the pixel driving circuit disposed in the island region of the same driving column. The power line segments VDD disposed in the pixel driving circuit of the same driving column in the island region may be connected to form a partial structure of the second power line V2. The plurality of first power lines V1 include a third power sub-line V13, and the third power sub-line V13 may be connected to one of the second electrode lines C2 through a via hole. Through the above arrangement, all power line segments VDD in the first bridge region 31 may be connected to the power line segments VDD in the island region. The plurality of pixel driving circuits being disposed on the same driving column may be understood as that the plurality of pixel driving circuits are connected to the same data line. In the exemplary embodiment, the pixel driving circuit for each driving column may be correspondingly provided with one power line, and it should be understood that in some exemplary embodiments, the pixel driving circuits for multiple driving columns may also be correspondingly provided with one power line.

As shown in FIGS. 16, 19, 24, 27, 28 and 35, the second gate layer may further include: a plurality of third electrode lines C3, the third electrode lines C3 is disposed on the third bridge region 33, in the third bridge region 33 the first electrodes of the capacitors in the pixel driving circuit disposed on the same driving row are connected to each other to form the third electrode lines C3, and the third bridge region 33 where the third electrode line C3 is disposed is connected to the island region where the second electrode line C2 is disposed. The first source-drain layer further includes: a plurality of third power lines V3, the plurality of third power lines are disposed on the third bridge region 33 where the third electrode lines C3 are disposed, the plurality of third power lines V3 may be connected to the pixel driving circuit disposed in the third bridge region 33 of the same driving column; the first source-drain layer may further includes an eighth connection line 408, the eighth connection line 408 is disposed on the third bridge region where the third power line C3 is disposed, and the eighth connection line 408 may be connected to one second power line V2 and one third electrode line C3. Through the above arrangement, the power line segments VDD in the island region and the power line segments VDD in the third bridge region may be connected.

As shown in FIGS. 16, 19, 24, 27, 28 and 35, the second gate layer may further include: a fourth electrode line C4, the fourth electrode line C4 is disposed on the fourth bridge region 34. In the fourth bridge region C4, the first electrodes of the capacitors in the pixel driving circuit disposed on the same driving row are connected to each other to form the fourth electrode line C4, and the fourth bridge region 34 where the fourth electrode line C4 is disposed is connected to the island region where the second electrode line C2 is disposed. As shown in FIGS. 16, 20, 25, 27, 31 and 36, the first source-drain layer may further include a plurality of fourth power lines V4, the fourth power lines V4 being disposed on the fourth bridge region 34 where the fourth electrode line C4 is disposed, the fourth power line V4 is connected to the pixel driving circuit disposed in the fourth bridge region of the same driving column. The power line segments VDD disposed in the pixel driving circuit of the same driving column in the fourth bridge region may be connected to form at least a partial structure of the fourth power line V4. When only one row of the pixel driving circuits is included in the fourth bridge region, at least a partial structure of the fourth power line V4 may be formed by the power line segment VDD in one pixel driving circuit. The plurality of fourth power lines V4 include a first power sub-line V41, the first power sub-line V41 is connected to one second power line V2, and the first power sub-line V41 and the eighth connection line 408 may be connected to the same second power line V2. Through the above arrangement, the power line segments VDD in the island region and the power line segments VDD in the fourth bridge region 34 may be connected to each other.

As shown in FIGS. 16, 19, 24, 27, 28 and 35, the second gate layer may further include: a fifth electrode line C5, the fifth electrode line C5 is disposed on the second bridge region 32, in the second bridge region 32, the first electrodes of the capacitors in the pixel driving circuit disposed on the same driving row are connected to each other to form the fifth electrode line C5, and the second bridge region where the fifth electrode line C5 is disposed is connected to the island region where the second electrode line C2 is disposed. The first source-drain layer may further include a plurality of fifth power lines V5, the fifth power lines V5 are disposed on the second bridge region 32 where the fifth electrode line C5 is disposed, the fifth power lines V5 are connected to the pixel driving circuit disposed in the second bridge region of the same driving column, and the power line segments VDD in the pixel driving circuit of the same driving column in the second bridge region may be connected to form at least a partial structure of the fifth power lines V5. When only one row of the pixel driving circuits is included in the second bridge region, at least a partial structure of the fifth power line V5 may be formed by the power line segment VDD in one pixel driving circuit. The plurality of fifth power lines V5 include a second power sub-line V52, the second power sub-line V52 is connected to one second power line V2. Through the above arrangement, the power line segments VDD in the island region and the power line segments VDD in the second bridge region 32 may be connected to each other.

As shown in FIGS. 16, 20, 25, 27, 31 and 36, the first source-drain layer may further include: a first data line D1, the first data line DI is disposed on the island region, as well as the first bridge region 31 and the fourth bridge region 34 that are connected to the island region, and the first data line D1 is connected to the plurality of pixel driving circuits disposed in the first bridge region and the fourth bridge region 34 of the same driving column 31. The first data line D1 may be formed by connecting the data line segments Da in the plurality of pixel driving circuits disposed in the first bridge region and the fourth bridge region 34 of the same driving column 31. As shown in FIGS. 16, 21, 26, 27, 32 and 37, in addition to the second source-drain layer including a third bridging portion 443, the second source-drain layer may also include: a fifth connection line 405, at least a partial structure of the fifth connection line 405 is disposed on the third bridge region 33 between the first island region 21 and the fourth island region 24, and the fifth connection line 405 is connected to the first data line D1 corresponding to the first island region 21 and the first data line D1 corresponding to the fourth island region 24, respectively, through a via hole. The first data line DI corresponding to the first island region 21 is disposed on the first island region 21, as well as the first bridge region 31 and the fourth bridge region 34 that are connected to the first island region 21; the first data line D1 corresponding to the fourth island region 24 is disposed on the fourth island region 24, as well as the first bridge region 31 and the fourth bridge region 34 that are connected to the fourth island region 24. Through the above arrangement, the first data lines D1 in the first island region 21 and the fourth island region 24 may be connected.

As shown in FIGS. 16, 20, 25, 27, 31 and 36, the first source-drain layer may further include: a second data line D2, disposed on the island region, as well as the second bridge region and the fourth bridge region that are connected to the island region, the second data line is connected to the plurality of pixel driving circuits disposed in the island region, the second bridge region 32, and fourth bridge region 34 of the same driving column. The second data line D2 may be formed by connecting the data line segments Da in the plurality of pixel driving circuits disposed on the island region, the second bridge region 32, and fourth bridge region 34 of the same driving column. The plurality of island regions also includes a fifth island region (not shown), the fifth island region is disposed on the same column as the first island region 21 and the fourth island region 24, the first island region 21 is disposed between the fourth island region 24 and the fifth island region, and the first island region 21 and the fifth island region are connected through the first bridge region 31. As shown in FIGS. 16, 21, 26, 27, 32 and 37, the second source-drain layer may further include: a sixth connection line 406, at least a partial structure of the sixth connection line 406 is disposed on the third bridge region 33 between the first island region 21 and the fourth island region 24 and the first bridge region 31 between the first island region 21 and the fifth island region, and the sixth connection line 406 is connected to the second data line D2 corresponding to the first island region 21, the second data line D2 corresponding to the fourth island region 24, and the second data line D2 corresponding to the fifth island region, respectively, through a via hole. The second data line D2 corresponding to the first island region 21 is disposed on the first island region 21, as well as the second bridge region 32 and the fourth bridge region 34 that are connected to the first island region; the second data line D2 corresponding to the fourth island region 24 is disposed on the fourth island region 24, as well as the second bridge region 32 and the fourth bridge region 34 that are connected to the fourth island region; the second data line D2 corresponding to the fifth island region is disposed on the fifth island region, as well as the second bridge region 32 and the fourth bridge region 34 that are connected to the fifth island region. Through the above arrangement, the second data line D2 corresponding to the first island region, the second data line D2 corresponding to the fourth island region 24, the second data line D2 corresponding to the fifth island region corresponding second data line D2 may be connected to each other.

As shown in FIGS. 16, 20, 25, 27, 31 and 36, the first source-drain layer may further include: a third data line D3, the third data line D3 is disposed on the island region, as well as the second bridge region 32 and the third bridge region 33 that are connected to the island region, and the third data line D3 is connected to the plurality of pixel driving circuits disposed in the second bridge region 32 and the third bridge region 33 of the same driving column. The third data line D3 may be formed by connecting the data line segments Da in the plurality of pixel driving circuits disposed in the second bridge region 32 and the third bridge region 33 of the same driving column. As shown in FIGS. 16, 21, 26, 27, 32 and 37, the second source-drain layer includes: a seventh connection line 407, at least a partial structure of the seventh connection line 407 is disposed on the first bridge region between the first island region 21 and the fifth island region, and the seventh connection line 407 is connected to the third data line D3 corresponding to the first island region 21 and the third data line D3 corresponding to the fifth island region. The third data line D3 corresponding to the first island region 21 is disposed on the first island region, as well as the second bridge region 32 and the third bridge region 33 that are connected to the first island region, and the third data line D3 corresponding to the fifth island region is disposed on the fifth island region, as well as the second bridge region 32 and the third bridge region 33 that are connected to the fifth island region. Through the above arrangement, the third data line D3 corresponding to the first island region 21 and the third data line D3 corresponding to the fifth island region may be connected.

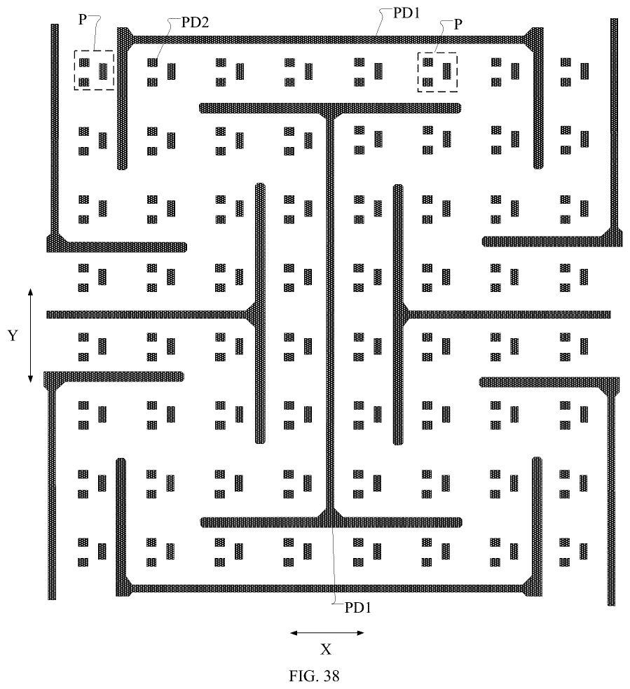

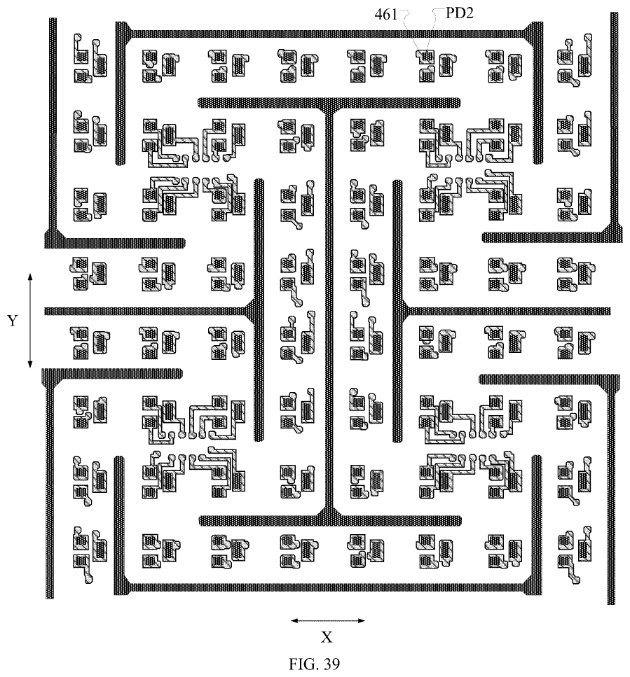

The display substrate may further include a pixel defining layer, the pixel defining layer is disposed on a side of the anode layer facing away from the base substrate, as shown in FIGS. 38, 39, FIG. 38 shows a structural layout of a pixel defining layer in FIG. 16, and FIG. 39 shows a structural layout of a pixel defining layer and an anode layer in FIG. 16. A hollow portion PD1 disposed on the hollow aperture region and a plurality of pixel apertures PD2 are defined on the pixel pixel defining layer, the plurality of pixel apertures PD2 are disposed on one-to-one correspondence with the plurality of electrode portions 461, and an orthographic projection of the pixel aperture PD2 on the base substrate is disposed on an orthographic projection of the electrode portion 461 corresponding to the pixel aperture PD2 on the base substrate. The light emitting unit OLED may be formed in the pixel aperture PD2. As shown in FIG. 38, the pixel apertures PD2 disposed on the same pixel unit form a pixel aperture group P, and the light emitting units disposed on the same pixel unit form a light emitting unit group. The pixel aperture group P includes three pixel apertures PD2, and the plurality of pixel apertures P are evenly distributed at equal intervals, i.e., each distance between the pixel aperture groups P of adjacent columns in the row direction is S1, and each distance between the pixel aperture groups P of adjacent rows in the column direction is S2, and S1 is equal to S2. Through the above arrangement, the light emitting units may be evenly distributed at equal intervals, thereby providing a more uniform display effect of the display substrate.

As shown in FIG. 25, a plurality of pixel driving circuits in the same pixel unit form a pixel driving circuit group PD, and at least a part of the pixel driving circuit groups PD are not evenly distributed at equal intervals. For example, a distance between two adjacent pixel driving circuit groups PD in the island region along the row direction X is less than a distance between two adjacent pixel driving circuit groups PD in the bridge region along the row direction X, and a distance between two adjacent pixel driving circuit groups PD in the island region along the column direction Y is less than a distance between two adjacent pixel driving circuit groups PD in the bridge region along the column direction Y.

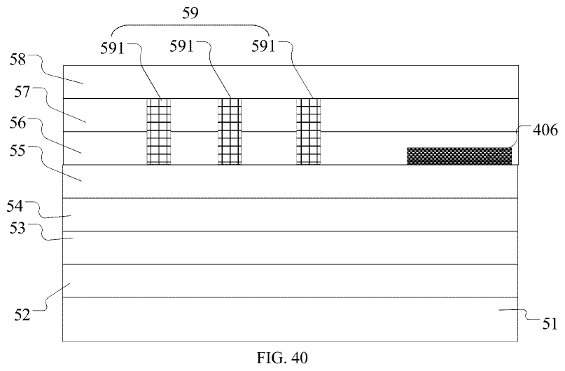

As shown in FIG. 40, FIG. 40 shows a partial sectional view along a dashed line CC in FIG. 27. The display substrate may further include a barrier layer 59, which may be disposed between a first passivation layer 57 and a second passivation layer 58. Three closed-shaped grooves running through the first passivation layer 57 and the first planarization layer 56 are defined on the first passivation layer 57, and the barrier layer 59 is filled in the grooves to form three closed-shaped barrier dams 591, as shown in FIGS. 16, 27. The barrier dams 591 surround the hollow aperture 1, and the three closed-shaped barrier dams 591 are sleeved in sequence. The barrier dams 591 may block water vapor at the hollow aperture 1 from entering a display region of the display substrate. A preset distance is provided between an orthographic projection of a side of the barrier dam 591 furthest from the hollow aperture 1 (i.e., an outermost barrier dam 591 of the plurality of barrier dams 591 sleeved) on the base substrate and an orthographic projection of the second source-drain layer on the base substrate. For example, as shown in FIG. 40, the right-most barrier dam 591 is at a preset distance from the sixth connection line 406. The preset distance may avoid accidentally etching the second source-drain layer when etching the groove. The preset distance may be 1 um to 5 um, for example, the preset distance may be 1 um, 1.5 um, 2 um, 3 um, 4 um, 5 um. It should to be noted that the barrier layer 59 may only include the barrier dam 591 disposed within the groove.

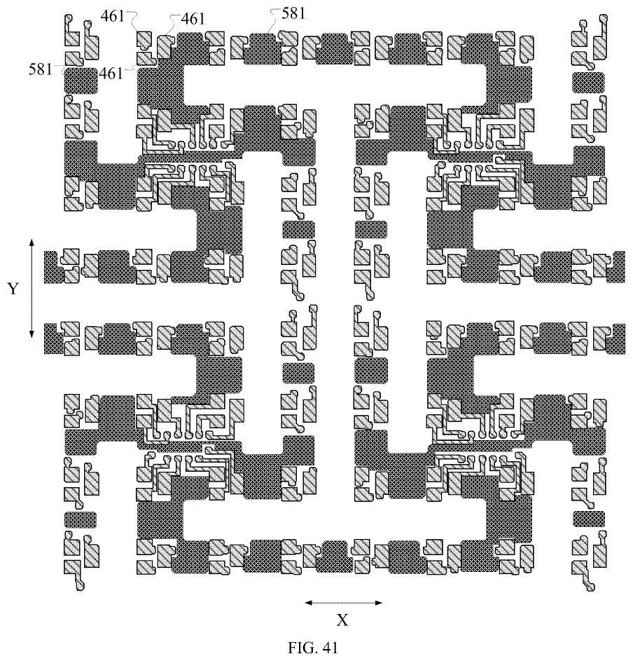

As shown in FIG. 41, FIG. 41 is a structural layout of a first passivation layer, a second passivation layer, and an anode layer in FIG. 16. The second passivation layer 58 is defined with a venting hole 581 running through the first passivation layer 57 and the second passivation layer 58; an orthographic projection of the electrode portion 461 on the anode layer on the base substrate does not overlap with an orthographic projection of the venting hole 581 on the base substrate. The venting hole 581 may be used for the first planarization layer 56 to release water vapor to avoid other layers on the first planarization layer 56 from bulging. The venting hole 581 may be filled with the pixel defining layer, and FIG. 41 does not illustrate via holes on the second passivation layer, the first passivation layer, aperture at the position of the hollow aperture.

In the exemplary embodiment, the display substrate may be defined with the hollow region on only a partial region of the display substrate, or the hollow aperture may be defined on the entire display substrate. The display substrate is provided with a region of the hollow aperture where the pixel density may be up to 200 PPI and the amount of stretching may be greater than 1%. The repeating unit shown in FIG. 16 may be square, and a side length of the square may be 1016 um.

The exemplary embodiment also provides a display apparatus including the above display substrate. The display apparatus may be a display apparatus such as a cell phone, a tablet computer, a television, and the like.

Other embodiments of the present disclosure will be apparent to those skilled in the art after those skilled in the art consider the specification and practice the technical solutions disclosed herein. The present disclosure is intended to cover any variations, uses, or adaptations of the present disclosure, which are in accordance with the general principles of the present disclosure and include common general knowledge or conventional technical means in the art that are not disclosed in the present disclosure. The specification and embodiments are illustrative, and the real scope and spirit of the present disclosure is defined by the appended claims.

It should be understood that the present disclosure is not limited to the precise structures that have been described above and shown in the drawings, and various modifications and changes can be made without departing from the scope thereof. The scope of the present disclosure is limited only by the appended claims.

1. A display substrate, comprising a plurality of hollow apertures, a plurality of island regions separated by the plurality of hollow apertures and bridge regions connected between the island regions, wherein the display substrate further comprises:
a plurality of pixel units, provided in the island regions and the bridge regions.

2. The display substrate according to claim 1, wherein the plurality of island regions are distributed in rows and columns, each island region is connected to four bridge regions, and each island region is connected to four island regions adjacent to the island region in a row direction and a column direction, respectively, through the four bridge regions.

3. The display substrate according to claim 2, wherein the hollow aperture is in I-shape and the I-shaped hollow aperture comprises: two first strip-shaped apertures opposite to each other, and a second strip-shaped aperture connected between the two first strip-shaped apertures;
the plurality of hollow apertures comprises a plurality of first hollow apertures distributed in rows and columns and a plurality of second hollow apertures distributed in rows and columns, the second strip-shaped aperture of the first hollow aperture extends along the column direction and the second strip-shaped aperture of the second hollow aperture extends along the row direction;
wherein the second hollow aperture is disposed between two adjacent first hollow apertures in the row direction, and the first hollow aperture is disposed between two adjacent second hollow apertures in the column direction;
the first hollow apertures in adjacent columns and in adjacent rows are staggered in the column direction, the second hollow apertures in adjacent rows and in adjacent columns are staggered in the row direction, and the first strip-shaped apertures of two first hollow apertures arranged in a staggered manner and the first strip-shaped apertures of two second hollow apertures arranged in a staggered manner form the island region;
the four bridge regions connected to the same island region comprise a first bridge region, a second bridge region, a third bridge region, and a fourth bridge region, at least a partial region of the first bridge region and the third bridge region is disposed between the second strip-shaped aperture of the first hollow aperture and the first strip-shaped aperture of the second hollow aperture, and at least a partial region of the second bridge region and the fourth bridge region is disposed between the first strip-shaped aperture of the first hollow aperture and the second strip-shaped aperture of the second hollow aperture.

4. The display substrate according to claim 3, wherein each island region is provided with four pixel units distributed in a two-by-two array, and each bridge region is provided with six pixel units distributed in the same direction, and the six pixel units are spaced apart along an extension direction of the bridge region where the six pixel units are disposed.

5. The display substrate according to claim 3, wherein the pixel unit comprises a plurality of pixel driving circuits and a plurality of light emitting units in one-to-one correspondence with the pixel driving circuits.

6. The display substrate according to claim 5, further comprising:
a base substrate;
a first gate layer, disposed on a side of the base substrate, wherein the first gate layer comprises:
a first gate line, wherein the first gate line is disposed on the first bridge region and is connected to the pixel driving circuit disposed on the first bridge region of the same driving row,
a second gate line, wherein the second gate line is disposed on the second bridge region and is connected to the pixel driving circuit disposed on the second bridge region in the same driving row, the first bridge region where the first gate line is disposed and the second bridge region where the second gate line is disposed are connected to the same island region, and the pixel driving circuit connected to the first gate line and the pixel driving circuit connected to the second gate line are disposed on the same driving row;
a first source-drain layer, disposed on a side of the first gate layer facing away from the base substrate, wherein the first source-drain layer comprises:
a first connection line, wherein at least a partial structure of the first connection line is disposed on the first bridge region where the first gate line is disposed, and the first connection line is connected to the first gate line and the second gate line, respectively, through a via hole.

7. The display substrate according to claim 6, wherein the first gate layer further comprises:
a third gate line, wherein at least a partial structure of the third gate line is disposed on the fourth bridge region, the fourth bridge region where the third gate line is disposed and the second bridge region where the second gate line is disposed are connected to the same island region;
the plurality of island regions comprise a first island region and a second island region adjacent to each other in the row direction, the first island region and the second island region are connected through the fourth bridge region, and the third gate line disposed in the fourth bridge region is connected to the second gate line corresponding to the first island region and the second gate line corresponding to the second island region;
wherein the second bridge region where the second gate line corresponding to the first island region is disposed is connected to the first island region, and the second bridge region where the second gate line corresponding to the second island region is disposed is connected to the second island region.

8. The display substrate according to claim 5, further comprising:
a base substrate;
a first gate layer, disposed on a side of the base substrate, wherein the first gate layer comprises:
a fourth gate line, wherein the fourth gate line is disposed on the fourth bridge region and is connected to the pixel driving circuit disposed in the fourth bridge region of the same driving row;
a fifth gate line, wherein the fifth gate line is disposed on the third bridge region and is connected to the pixel driving circuit disposed in the third bridge region of the same driving row, and the pixel driving circuit connected to the fourth gate line and the pixel driving circuit connected to the fifth gate line are disposed on the same driving row;
a first source-drain layer, disposed on a side of the first gate layer facing away from the base substrate, wherein the first source-drain layer comprises:
a second connection line, wherein at least a partial structure of the second connection line is disposed on the third bridge region where the fifth gate line is disposed, and the second connection line is connected to the fourth gate line and the fifth gate line, respectively, through a via hole.

9. The display substrate according to claim 8, wherein the first gate layer further comprises:
a sixth gate line, wherein at least a partial structure of the sixth gate line is disposed on the second bridge region, the second bridge region where the sixth gate line is disposed and the fourth bridge region where the fourth gate line is disposed are connected to the same island region;
the plurality of island regions further comprises a first island region, a third island region disposed on the same row, the first island region and the third island region are connected through the second bridge region;
the sixth gate line disposed on the second bridge region is connected to the fourth gate line corresponding to the first island region and the fourth gate line corresponding to the third island region;
the fourth bridge region where the fourth gate line corresponding to the first island region is disposed is connected to the first island region, and the fourth bridge region where the fourth gate line corresponding to the third island region is disposed is connected to the third island region.

10. The display substrate according to claim 5, further comprising:
a base substrate;
a first gate layer, disposed on a side of the base substrate, wherein the first gate layer comprises:
a seventh gate line, wherein the seventh gate line is disposed on the first bridge region and is connected to the pixel driving circuit disposed in the first bridge region of the same driving row;
an eighth gate line, wherein the eighth gate line is disposed on the island region and is connected to the pixel driving circuit disposed in the island region of the same driving row, the island region where the eighth gate line is disposed is connected to the first bridge region where the seventh gate line is disposed, and the pixel driving circuit connected to the seventh gate line and the pixel driving circuit connected to the eighth gate line are disposed on the same driving row;
a first source-drain layer, disposed on a side of the first gate layer facing away from the base substrate, wherein the first source-drain layer comprises:
a third connection line, wherein at least a partial structure of the third connection line is disposed on the first bridge region where the seventh gate line is disposed, and the third connection line is connected to the seventh gate line and the eighth gate line, respectively, through a via hole.

11. The display substrate according to claim 10, wherein the first gate layer further comprises:
a ninth gate line, wherein the ninth gate line is disposed on the third bridge region and is connected to the pixel driving circuit disposed in the third bridge region of the same driving row, the island region where the eighth gate line is disposed is connected to the third bridge region where the ninth gate line is disposed, and the pixel driving circuit connected to the ninth gate line and the pixel driving circuit connected to the eighth gate line are disposed on the same driving row;
the first source-drain layer comprises:
a fourth connection line, wherein at least a partial structure of the fourth connection line is disposed on the third bridge region where the ninth gate line is disposed, and the fourth connection line is connected to the ninth gate line and the eighth gate line, respectively, through a via hole.

12. The display substrate according to claim 11, wherein the first gate layer further comprises:
a tenth gate line, wherein at least a partial structure of the tenth gate line is disposed on the second bridge region, the second bridge region where the tenth gate line is disposed is connected to the island region where the eighth gate line is disposed;
an eleventh gate line, wherein at least a partial structure of the eleventh gate line is disposed on the fourth bridge region, the fourth bridge region where the eleventh gate line is disposed is connected to the island region where the eighth gate line is disposed;
the plurality of island regions comprise a first island region, a second island region, and a third island region disposed on the same row, the first island region is disposed between the second island region and the third island region, the first island region and the third island region are connected through the second bridge region, and the first island region and the second island region are connected through the fourth bridge region;
the tenth gate line disposed in the second bridge region is connected to the fourth connection line corresponding to the first island region and the fourth connection line corresponding to the third island region through a via hole;
the eleventh gate line disposed in the fourth bridge region is connected to the fourth connection line corresponding to the first island region and the fourth connection line corresponding to the second island region through a via hole;
wherein the third bridge region where the fourth connection line corresponding to the first island region is disposed is connected to the first island region, the third bridge region where the fourth connection line corresponding to the third island region is disposed is connected to the third island region, and the third bridge region where the fourth connection line corresponding to the second island region is disposed is connected to the second island region.

13. The display substrate according to claim 5, further comprising:
a base substrate;
a first source-drain layer, disposed on a side of the base substrate, wherein the first source-drain layer comprises:
a first data line, disposed on the island region, as well as the first bridge region and the fourth bridge region that are connected to the island region, wherein the first data line is connected to the plurality of pixel driving circuits disposed in the first bridge region and the fourth bridge region of the same driving column;
the plurality of island regions comprise a first island region and a fourth island region adjacent to each other in the column direction, the first island region and the fourth island region are connected through the third bridge region;
a second source-drain layer, disposed on a side of the first source-drain layer facing away from the base substrate, wherein the second source-drain layer comprises:
a fifth connection line, wherein at least a partial structure of the fifth connection line is disposed on the third bridge region between the first island region and the fourth island region, and the fifth connection line is connected to the first data line corresponding to the first island region and the first data line corresponding to the fourth island region, respectively, through a via hole;
the first data line corresponding to the first island region is disposed on the first island region as well as the first bridge region and the fourth bridge region that are connected to the first island region, and the first data line corresponding to the fourth island region is disposed on the fourth island region as well as the first bridge region and the fourth bridge region that are connected to the fourth island region.

14. The display substrate according to claim 5, further comprising:
a base substrate;
a first source-drain layer, disposed on a side of the base substrate, wherein the first source-drain layer comprises:
a second data line, disposed on the island region as well as the second bridge region and the fourth bridge region that are connected to the island region, wherein the second data line is connected to the plurality of pixel driving circuits disposed in the island region, the second bridge region and the fourth bridge region of the same driving column;
the plurality of island regions comprise a first island region, a fourth island region, and a fifth island region disposed on the same column, wherein the first island region is disposed between the fourth island region and the fifth island region, the first island region and the fourth island region are connected through the third bridge region, and the first island region and the fifth island region are connected through the first bridge region;
a second source-drain layer, disposed on a side of the first source-drain layer facing away from the base substrate, wherein the second source-drain layer comprises:
a sixth connection line, wherein at least a partial structure of the sixth connection line is disposed on the third bridge region between the first island region and the fourth island region, and the first bridge region between the first island region and the fifth island region, and the sixth connection line is connected to the second data line corresponding to the first island region, the second data line corresponding to the fourth island region, and the second data line corresponding to the fifth island region, respectively, through a via hole;
the second data line corresponding to the first island region is disposed on the first island region, as well as the second bridge region and the fourth bridge region that are connected to the first island region, the second data line corresponding to the fourth island region is disposed on the fourth island region, as well as the second bridge region and the fourth bridge region that are connected to the fourth island region, and the second data line corresponding to the fifth island region is disposed on the fifth island region, as well as the second bridge region and the fourth bridge region that are connected to the fifth island region.

15. The display substrate according to claim 5, further comprising:
a base substrate;
a first source-drain layer, disposed on a side of the base substrate, wherein the first source-drain layer comprises:
a third data line, wherein the third data line is disposed on the island region, as well as the second bridge region and the third bridge region that are connected to the island region, the third data line is connected to the plurality of pixel driving circuits disposed in the second bridge region of the same driving column and third bridge region;
the plurality of island regions comprise a first island region and a fifth island region adjacent to each other in the column direction, wherein the first island region and the fifth island region are connected through the first bridge region;
a second source-drain layer, disposed on a side of the first source-drain layer facing away from the base substrate, wherein the second source-drain layer comprises:
a seventh connection line, wherein at least a partial structure of the seventh connection line is disposed on the first bridge region between the first island region and the fifth island region, and the seventh connection line is connected to the third data line corresponding to the first island region and the third data line corresponding to the fifth island region, respectively, through a via hole;
the third data line corresponding to the first island region is disposed on the first island region, as well as the second bridge region and the third bridge region that are connected to the first island region, and the third data line corresponding to the fifth island region is disposed on the fifth island region, as well as the second bridge region and the third bridge region that are connected to the fifth island region.

16. The display substrate according to claim 5, wherein the pixel driving circuits comprise capacitors, the capacitor comprises first electrode, and the display substrate further comprises:
a base substrate;
a first gate layer, disposed on a side of the base substrate;
a second gate layer, disposed on a side of the first gate layer facing away from the base substrate, wherein the second gate layer comprises:
at least one first electrode line, wherein the first electrode line is disposed on the first bridge region, and in the first bridge region, the first electrodes of the capacitors disposed in the pixel driving circuit of the same driving row are connected to each other to form the first electrode line;
at least one second electrode line, wherein the second electrode line is disposed on the island region; in the island region, the first electrodes of the capacitors disposed in the pixel driving circuit of the same driving row are connected to each other to form the second electrode line, and the first bridge region where the first electrode line is disposed is connected to the island region where the second electrode line is disposed;
a first source-drain layer, disposed on a side of the second gate layer facing away from the base substrate, wherein the first source-drain layer comprises:
at least one first power line, wherein the first power line is disposed on the first bridge region, connected to the pixel driving circuit disposed in the first bridge region of the same driving column, and at least one first power line is connected to one second electrode line through a via hole;
at least one second power line, wherein the second power line is disposed on the island region, the island region where the second power line is disposed is connected to the first bridge region where the first power line is disposed, and the second power line is connected to the pixel driving circuit disposed in the island region of the same driving column.

17. The display substrate according to claim 16, wherein the second gate layer further comprises:
at least one third electrode line, wherein the third electrode line is disposed on the third bridge region; in the third bridge region, the first electrodes of the capacitors in the pixel driving circuit disposed on the same driving row are connected to each other to form the third electrode line, and the third bridge region where the third electrode line is disposed is connected to the island region where the second electrode line is disposed;
the first source-drain layer further comprises:
at least one third power line, wherein the third power line is disposed on the third bridge region where the third electrode line is disposed, connected to the pixel driving circuit disposed in the third bridge region of the same driving column;
an eighth connection line, wherein the eighth connection line is disposed on the third bridge region where the third power line is disposed, and connected to one second power line and one third electrode line
wherein the second gate layer further comprises:
a fourth electrode line, wherein the fourth electrode line is disposed on the fourth bridge region; in the fourth bridge region, the first electrodes of the capacitors in the pixel driving circuit disposed on the same driving row are connected to each other to form the fourth electrode line, and the fourth bridge region where the fourth electrode line is disposed is connected to the island region where the second electrode line is disposed;
the first source-drain layer further comprises:
at least one fourth power line, wherein the fourth power line is disposed on the fourth bridge region where the fourth electrode line is disposed, connected to the pixel driving circuit disposed in the fourth bridge region of the same driving column;
wherein at least one fourth power line comprises a first power sub-line, and the first power sub-line is connected to one second power line-wherein the second gate layer further comprises:
a fifth electrode line, wherein the fifth electrode line is disposed on the second bridge region; in the second bridge region, the first electrodes of the capacitors in the pixel driving circuit disposed on the same driving row are connected to each other to form the fifth electrode line, and the second bridge region where the fifth electrode line is disposed is connected to the island region where the second electrode line is disposed;
the first source-drain layer further comprises:
at least one fifth power line, wherein the fifth power line is disposed on the second bridge region where the fifth electrode line is disposed, and connected to the pixel driving circuit disposed in the second bridge region of the same driving column;
at least one fifth power line comprises a second power sub-line, and the second power sub-line is connected to one second power line.

18-19. (canceled)

20. The display substrate according to claim 5, wherein the plurality of pixel driving circuits in the same pixel unit form a pixel driving circuit group, and the plurality of light emitting units in the same pixel unit form a light emitting unit group;
the light emitting unit groups are evenly distributed at equal intervals and at least a part of the pixel driving circuit groups are not evenly distributed at equal intervals;
wherein a distance between two adjacent pixel driving circuit groups in the island region along the row direction is less than a distance between two adjacent pixel driving circuit groups in the bridge region along the row direction;
a distance between two adjacent pixel driving circuit groups in the island region along the column direction is less than a distance between two adjacent pixel driving circuit groups in the bridge region along the column direction.

21. (canceled)

22. The display substrate according to claim 5, wherein the pixel driving circuit comprises a driving transistor, a switching transistor, and a capacitor;
a first electrode of the driving transistor is connected to a power line, and a second electrode of the driving transistor is connected to the light emitting unit;
a first electrode of the switching transistor is connected to a data line, a second electrode of the switching transistor is connected to a gate of the driving transistor, and a gate of the switching transistor is connected to a gate line;
a first electrode of the capacitor is connected to the power line, and a second electrode of the capacitor is connected to the gate of the driving transistor;
the display substrate further comprises:
a base substrate;
an active layer, disposed on a side of the base substrate, wherein a partial structure of the active layer is configured to form a channel region of the driving transistor and a channel region of the switching transistor;
a first gate layer, disposed on a side of the active layer facing away from the base substrate, wherein a partial structure of the first gate layer is configured to form the gate line, the gate of the driving transistor and the gate of the switching transistor, and the second electrode of the capacitor;
a second gate layer, disposed on a side of the first gate layer facing away from the base substrate, wherein a partial structure of the second gate layer is configured to form the first electrode of the capacitor;
a first source-drain layer, disposed on a side of the second gate layer facing away from the base substrate, a partial structure of the first source-drain layer is configured to form the data line and the power line.

23-24. (canceled)

25. A display apparatus comprising the display substrate according to claim 1.
